(19) United States
(12) Patent Application Publication
(10) Pub. No.: US 2006/0215853 A1
(43) Pub. Date: Sep. 28, 2006

(54) Apparatus, method, and computer program product for reproducing sound by dividing sound field into non-reduction region and reduction region

(75) Inventors: Takahiro Hiruma, Tokyo (JP); Akihiko Enamito, Kanagawa (JP); Takahiro Suzuki, Tokyo (JP); Rika Hosaka, Kanagawa (JP); Takumi Hara, Kanagawa (JP)

Correspondence Address: Charles N.J. Ruggiero;Ohlandt, Greeley, Ruggiero & Perle, L.L.P., 10th Floor, One Landmark Square, Stamford, CT, 06901-2682, US

(73) Assignee: Kabushiki Kaisha Toshiba

(21) Appl. No.: 11/363,429

(22) Filed: Feb. 27, 2006

(30) Foreign Application Priority Data
Mar. 23, 2005 (JP) 2005-084459

(51) Int. Cl. H04R 1/40; H03G 9/00

(52) U.S. Cl. 381/97; 381/102

(57) ABSTRACT

A sound reproducing apparatus includes an amplitude and phase adjusting unit that adjusts amplitude and phase of a sound signal which is supplied as an input, and outputs an adjusted sound signal; a first sound source that outputs a first sound based on the sound signal; and a second sound source that outputs a second sound based on the adjusted sound signal, and that has a different distance decay rate from the first sound source, the distance decay rate representing a ratio of attenuation of sound pressure of sound output from a sound source to a distance from the sound source; wherein the amplitude and phase adjusting unit adjusts the amplitude and the phase of the sound signal, so as to restrain a synthesis sound pressure that is a combination of a sound pressure of the first sound which is calculated based on the distance decay rate of the first sound source, and a sound pressure of the second sound which is calculated based on the distance decay rate of the second sound source, at a predetermined distance from the first sound source.

### CROSS-REFERENCE TO RELATED APPLICATIONS

This application is based upon and claims the benefit of priority from the prior Japanese Patent Application No. 2005-84459, filed on Mar. 23, 2005; the entire contents of which are incorporated herein by reference.

### BACKGROUND OF THE INVENTION

1. Field of the Invention

The present invention relates to an apparatus, a method, and a computer program product for reproducing sound by dividing a sound field into a non-reduction region and a reduction region, utilizing the active noise reduction technique.

2. Description of the Related Art

The technique of performing sound field control on reproduced sound through adjustments of sound signals and the locations of speakers has been known and utilized in sound reproducing apparatuses for reproducing the sound signals of contents that are recorded on recording media such as cassette tapes, compact disks, and minidisks. As in the 5.1-ch system that has a surround-sound effect, for example, speakers and control microphones are arranged in a scattered fashion so as to surround a predetermined region, and with the use of the active noise reduction technique, the increase and decrease in sound pressure are made varied greatly between the inside and the outside of the surrounded region. In this manner, the sound field is divided into a non-reduction region and a reduction region. Here, the “active noise reduction” is to reduce sound by outputting a control sound from a speaker that is provided as an additional sound source at a distance from the speaker which serves as a main sound source.

In a sound reproducing apparatus having speakers arranged in a scattered fashion, the phase of the sound signal for reproducing low pitch sound is varied to change the level of the synthesis sound pressure of the sounds output from the speakers, without a complicated structure such as a tone control circuit. In this manner, low pitch sound can be controlled. Such a technique is disclosed in Japanese Patent Publication No. 2639929, for example.

Adoption of such a sound field control technique, however, requires a large placement space, and the placement and the wiring are complicated, because the speakers are arranged in a scattered fashion. Therefore, apparatuses with integrated layouts in which speakers are concentrated in the front area have been developed. With such integrated layouts, however, the active noise reduction technique cannot be utilized for the sound reduction in which a control sound is output from an additional sound source provided at a distance from the main sound source.

### SUMMARY OF THE INVENTION

According to one aspect of the present invention, a sound reproducing apparatus includes an amplitude and phase adjusting unit that adjusts amplitude and phase of a sound signal which is supplied as an input, and outputs an adjusted sound signal; a first sound source that outputs a first sound based on the sound signal; and a second sound source that outputs a second sound based on the adjusted sound signal, and that has a different distance decay rate from the first sound source, the distance decay rate representing a ratio of attenuation of sound pressure of sound output from a sound source to a distance from the sound source; wherein the amplitude and phase adjusting unit adjusts the amplitude and the phase of the sound signal, so as to restrain a synthesis sound pressure that is a combination of a sound pressure of the first sound which is calculated based on the distance decay rate of the first sound source, and a sound pressure of the second sound which is calculated based on the distance decay rate of the second sound source, at a predetermined distance from the first sound source.

According to another aspect of the present invention, a sound reproducing apparatus includes a first sound source that has a length equal to or larger than a predetermined length in a predetermined direction, and outputs a first sound based on a first sound signal; a second sound source that has a length equal to or smaller than the predetermined length in the predetermined direction, and outputs a second sound based on a second sound signal; and an amplitude and phase adjusting unit that adjusts amplitude and phase of one of the first sound signal and the second sound signal to be input, so as to restrain a synthesis sound pressure which is a combination of a sound pressure of the first sound and a sound pressure of the second sound at a distance from one of the first sound source and the second sound source, the distance being longer than a distance represented by a value obtained by dividing the predetermined length by A, and that outputs the adjusted one of the first sound signal and the second sound signal as the other one of the first sound signal and the second sound signal.

According to still another aspect of the present invention, a sound reproducing apparatus includes an amplitude and phase adjusting unit that adjusts amplitude and phase of a sound signal which is supplied as an input, and outputs an adjusted sound signal; a first sound source that is selected from a plurality of sound sources arranged in a matrix fashion; a second sound source that is selected from the plurality of sound sources, and has a different distance decay rate from the first sound source, the distance decay rate representing a ratio of attenuation of sound pressure of sound output from a sound source to a distance from the sound source; a delay time determining unit that determines a delay time for delaying the sound signal, so as to restrain a synthesis sound pressure which is a combination of a sound pressure of a sound output from the first sound source and a sound pressure of a sound output from the second sound source at a predetermined distance from the first sound source, and that outputs a delayed sound signal which is obtained by delaying the sound signal by the delay time to the first sound source; wherein the amplitude and phase adjusting unit adjusts amplitude and phase of the sound signal, so as to restrain the synthesis sound pressure, and that outputs the adjusted sound signal to the second sound source.

According to still another aspect of the present invention, a sound reproducing method includes adjusting amplitude and phase of a sound signal which is supplied as an input so as to restrain a synthesis sound pressure which is a combination of a sound pressure of a first sound output from a first sound source and a sound pressure of a second sound output from a second sound source at a predetermined distance from the first sound source, the first sound source outputting the first sound based on the sound signal, the second sound source outputting the second sound based on an adjusted sound signal and has a different distance decay rate from the first sound source, the distance decay rate representing a ratio of attenuation of sound pressure of sound output from a sound source to a distance from the sound source, and outputting the adjusted sound signal.

According to still another aspect of the present invention, a sound reproducing method includes adjusting amplitude and phase of one of a first sound signal to be input to a first sound source and a second sound signal to be input to a second sound source, so as to restrain a synthesis sound pressure which is a combination of a sound pressure of a first sound and a sound pressure of a second sound at a distance from one of the first sound source and the second sound source, the distance being longer than a distance represented by a value obtained by dividing a predetermined length by π, the first sound source having a length equal to or larger than the predetermined length in a predetermined direction and outputting the first sound based on the first sound signal, the second sound source having a length equal to or smaller than the predetermined length in the predetermined direction and outputting the second sound based on the second sound signal, and outputting the adjusted one of the first sound signal and the second sound signal as the other one of the first sound signal and the second sound signal.

According to still another aspect of the present invention, a sound reproducing method includes determining a delay time for delaying a sound signal to be input to a first sound source selected from a plurality of sound sources arranged in a matrix fashion, so as to restrain a synthesis sound pressure which is a combination of a sound pressure of a sound output from the first sound source and a sound pressure of a sound output from a second sound source at a predetermined distance from the first sound source, the second sound source having a different distance decay rate from the first sound source and being selected from the plurality of sound sources, the distance decay rate representing a ratio of attenuation of sound pressure of sound output from a sound source to a distance from the sound source, and outputting a delayed sound signal which is obtained by delaying the sound signal by the delay time to the first sound source; and adjusting amplitude and phase of the sound signal, so as to restrain the synthesis sound pressure, and outputting an adjusted sound signal to the second sound source.

According to still another aspect of the present invention, a computer program product having a computer readable medium including programmed instructions for performing sound reproduction, wherein the instructions, when executed by a computer, cause the computer to perform: adjusting amplitude and phase of a sound signal which is supplied as an input so as to restrain a synthesis sound pressure which is a combination of a sound pressure of a first sound output from a first sound source and a sound pressure of a second sound output from a second sound source at a predetermined distance from the first sound source, the first sound source outputting the first sound based on the sound signal, the second sound source outputting the second sound based on an adjusted sound signal and has a different distance decay rate from the first sound source, the distance decay rate representing a ratio of attenuation of sound pressure of sound output from a sound source to a distance from the sound source, and outputting the adjusted sound signal.

According to still another aspect of the present invention, a computer program product having a computer readable medium including programmed instructions for performing sound reproduction, wherein the instructions, when executed by a computer, cause the computer to perform: adjusting amplitude and phase of one of a first sound signal to be input to a first sound source and a second sound signal to be input to a second sound source, so as to restrain a synthesis sound pressure which is a combination of a sound pressure of a first sound and a sound pressure of a second sound at a distance from one of the first sound source and the second sound source, the distance being longer than a distance represented by a value obtained by dividing a predetermined length by π, the first sound source having a length equal to or larger than the predetermined length in a predetermined direction and outputting the first sound based on the first sound signal, the second sound source having a length equal to or smaller than the predetermined length in the predetermined direction and outputting the second sound based on the second sound signal, and outputting the adjusted one of the first sound signal and the second sound signal as the other one of the first sound signal and the second sound signal.

According to still another aspect of the present invention, a computer program product having a computer readable medium including programmed instructions for performing sound reproduction, wherein the instructions, when executed by a computer, cause the computer to perform: determining a delay time for delaying a sound signal to be input to a first sound source selected from a plurality of sound sources arranged in a matrix fashion, so as to restrain a synthesis sound pressure which is a combination of a sound pressure of a sound output from the first sound source and a sound pressure of a sound output from a second sound source at a predetermined distance from the first sound source, the second sound source having a different distance decay rate from the first sound source and being selected from the plurality of sound sources, the distance decay rate representing a ratio of attenuation of sound pressure of sound output from a sound source to a distance from the sound source, and outputting a delayed sound signal which is obtained by delaying the sound signal by the delay time to the first sound source; and adjusting amplitude and phase of the sound signal, so as to restrain the synthesis sound pressure, and outputting an adjusted sound signal to the second sound source.

### BRIEF DESCRIPTION OF THE DRAWINGS

FIG. 1 is a block diagram of the structure of a sound reproducing apparatus in accordance with a first embodiment of the present invention;

FIGS. 2A and 2B show the sound pressure level in relation to the distance from a point sound source;

FIGS. 3A and 3B show the sound pressure level in relation to the distance from a linear sound source;

FIGS. 4A and 4B show the sound pressure level in relation to the distance from a plane sound source;

FIG. 5 shows the sound pressure of the sound output from each sound source at a sound receiving point;

FIG. 6 is a flowchart of an amplitude and phase adjusting operation to be performed in the sound reproducing apparatus in accordance with the first embodiment;

FIGS. 7A and 7B show the sound pressure attenuation observed with one point sound source, in the form of three-dimensional coordinates;

FIGS. 8A and 8B show the sound pressure attenuation observed with three point sound sources, in the form of three-dimensional coordinates;

FIG. 9 shows the sound pressure attenuation observed with one point sound source, in the form of two-dimensional coordinates;

FIG. 10 shows the sound pressure attenuation observed with three point sound sources, in the form of two-dimensional coordinates;

FIG. 11 shows the structure of a main sound source and an additional sound source;

FIG. 12 shows the relationship among the main sound source, the additional sound source, and the location to minimize the synthesis sound pressure;

FIG. 13 shows the characteristics of a sound source to be used as the basis on a simulation;

FIG. 14 shows the decrease in sound pressure level in a case where region dividing is performed;

FIG. 15 shows the decrease in sound pressure level in a case where region dividing is performed;

FIG. 16 is a block diagram of the structure of a sound reproducing apparatus in accordance with a second embodiment of the present invention;

FIG. 17 is a flowchart of an amplitude and phase adjusting operation to be performed in the sound reproducing apparatus in accordance with the second embodiment;

FIG. 18 is a block diagram of the structure of a sound reproducing apparatus in accordance with a third embodiment of the present invention;

FIG. 19 shows the relationship between frequency and phase;

FIG. 20 shows an exemplary structure in which a main sound source and an additional sound source are selected from a matrix speaker formed with element speakers;

FIG. 21 shows the sound pressure of sounds output from speakers selected from the matrix speaker, in relation to the distance from the sound sources;

FIGS. 22A and 22B show an exemplary structure in which a main sound source and an additional sound source are selected from a matrix speaker formed with element speakers;

FIG. 23 shows conditions for placement of a matrix speaker;

FIG. 24 shows the relationship between the sound pressure level and the distance from the matrix speaker; and

FIG. 25 shows the relationship between a decrease in sound pressure level and the distance from the matrix speaker.

### DETAILED DESCRIPTION OF THE INVENTION

The following is a description of preferred embodiments of a sound reproducing apparatus, a sound reproducing method, and a sound reproducing program in accordance with the present invention, with reference to the accompanying drawings.

A sound reproducing apparatus in accordance with a first embodiment outputs sound signals of different amplitudes and opposite phases from two speakers of different distance decay rates from each other, restrains the synthesis sound pressure generated from the sound output from each speaker at a predetermined distance, and divides the sound field into a non-reduction region and a reduction region. Here, the “distance decay rate” is the ratio of decrease of the pressure of the sound output from a sound source in accordance with the distance from the sound source.

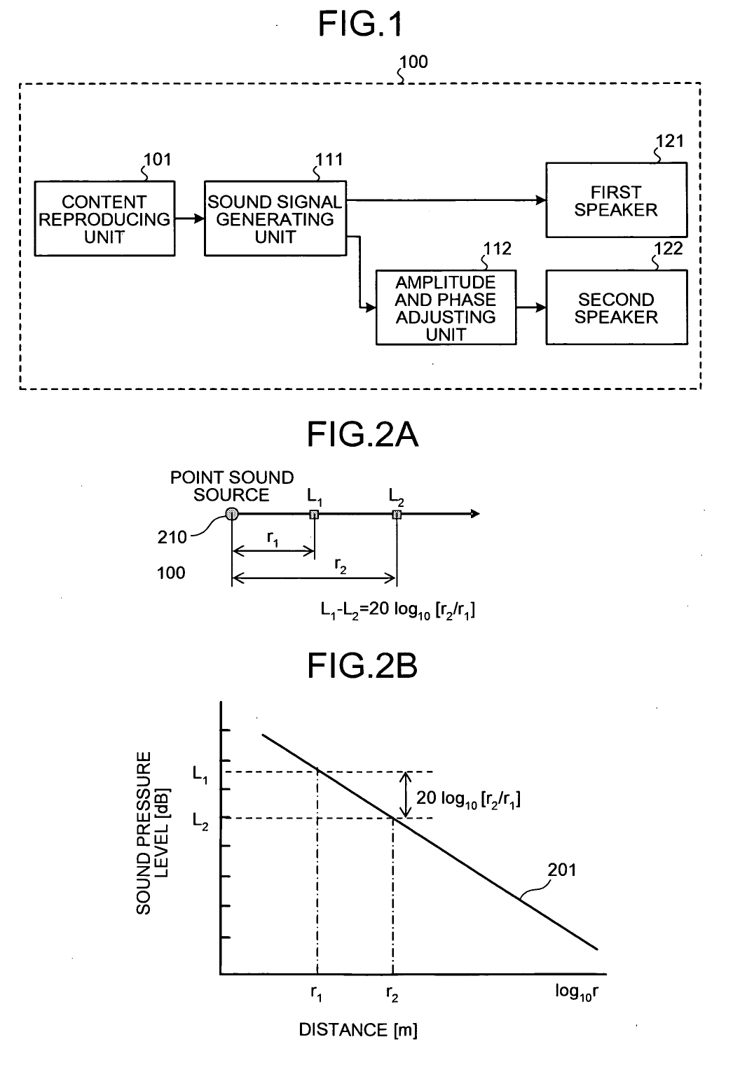

FIG. 1 is a block diagram of the structure of a sound reproducing apparatus 100 in accordance with the first embodiment. As shown in FIG. 1, the sound reproducing apparatus 100 includes a content reproducing unit 101, a sound signal generating unit 111, an amplitude and phase adjusting unit 112, a first speaker 121, and a second speaker 122.

The content reproducing unit 101 reproduces the sound signals (source sound signals) of contents that are recorded on recording media such as cassette tapes, compact disks, and minidisks.

The sound signal generating unit 111 performs signal processing such as D-A conversion and amplification on the source sound signals that are supplied from the content reproducing unit 101. The sound signal generating unit 111 then generates a first sound signal for audio output, and outputs the first sound signal to the first speaker 121 and the amplitude and phase adjusting unit 112.

The amplitude and phase adjusting unit 112 determines the amplitude and the phase of the first sound signal supplied from the sound signal generating unit 111, so as to restrain the synthesis sound pressure that represents the synthesis value of the sound pressures of the first speaker 121 and the second speaker 122 at the predetermined distance. The amplitude and phase adjusting unit 112 then outputs a second sound signal that is adjusted to the determined amplitude and phase to the second speaker 122.

More specifically, the amplitude and phase adjusting unit 112 determines the amplitude of the second sound signal in accordance with the distance decay rate of the sound output from each speaker, so that the sound pressures at the predetermined distance from each speaker become equal to each other. The amplitude and phase adjusting unit 112 also determines the phase of the second sound signal, so that the phase of the sound output from the second speaker 122 becomes opposite to the phase of the sound output from the first speaker 121. Here, the distance decay rate of each speaker takes a known value. Further, the relationship between the first sound signal and the sound output from the first speaker 121 to which the first sound signal is supplied is represented by a known value, and the relationship between the second sound signal and the sound output from the second speaker 122 to which the second sound signal is supplied is represented by a known value. In this manner, the synthesis sound pressure of the speakers at the predetermined distance becomes zero in theory.

The first speaker 121 and the second speaker 122 generate sound in accordance with sound signals, so as to output sound. The first speaker 121 is equivalent to the main sound source in accordance with the active noise reduction method, and the second speaker 122 is equivalent to the additional sound source.

Where the sounds output from the two speakers are reduced in accordance with the active noise reduction method, according to which the noise reduction on the sound output from the main sound source is realized with the output of a control sound from the additional sound source, the sound field is divided into a region of reducing sound (a reduction region) and a region in which the sound remains (a non-reduction region) according to the distance from the sound source based on the difference in distance decay rates between the types of sound sources, even if the sounds are output in substantially the same direction from substantially the same points. In the following, the types of sound sources and a specific method of dividing a sound field are described in detail.

In general, sound sources can be classified into point sound sources, linear sound sources, and plane sound sources. A point sound source is a sufficiently small sound source in relation to the propagation distance and may appear to emit sound from a single point. A linear sound source forms a sound field in which numerous independent point sound sources are densely arranged on a straight line. A plane sound source forms a sound field in which numerous independent point sound sources are distributed on a plane. In the following, the general characteristics of each type of sound source are described.

FIGS. 2A and 2B show the sound pressure level in relation to the distance from a point sound source. When a point sound source 210 shown in FIG. 2A generates sound with sound power W (watt) uniformly in all directions, the sound intensity I (W/m²) is expressed by the following equation (1):

$$I = \frac{W}{4 π {r}^{2}} ( W / {m}^{2} ) \qquad ( 1 )$$

where r(m) represents the distance from the sound source to the sound receiving point. As expressed by the equation (1), the sound intensity of the point sound source characteristically decreases in inverse proportion to the square of the distance.

If the sound pressure level Lₚ (dB: decibel) is assigned to the equation (1), the following equation (2) is obtained:
Lₚ=L_{W}−10 log₁₀(4π r²)=L_{W}−20 log₁₀ r−11 (dB) (2)

where L_{W} (dB) represents the power level of the sound source. As shown in the equation, the relationship between the logarithm of the distance r from the point sound source and the sound pressure level Lₚ is as indicated by a straight line 201 shown in FIG. 2B.

Further, where the pressure levels at distances r₁ and r₂ from the point sound source 210 are represented by L₁ and L₂ as shown in FIG. 2A, the following equation (3) is obtained:

$${L}_{2} = {L}_{1} - 20 {log}_{10} ( \frac{{r}_{2}}{{r}_{1}} ) ( dB ) \qquad ( 3 )$$

Thus, when the distance is doubled, the sound pressure level drops by approximately 6 dB, since log₁₀2 is approximately 0.3.

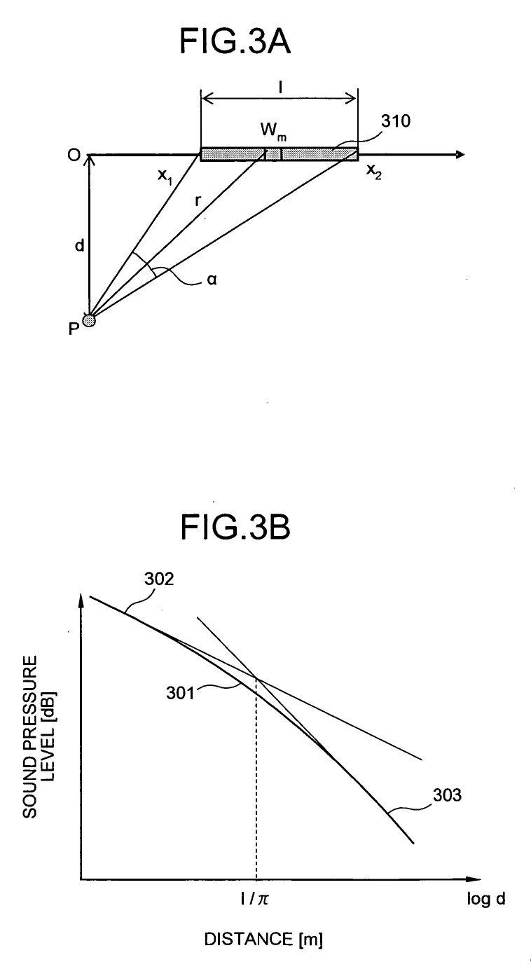

FIGS. 3A and 3B show the sound pressure level in relation to the distance from a linear sound source. As shown in FIG. 3A, when a linear sound source 310 having a length of 1 (m) existing between points x₁ and x₂ generates sound, the sound intensity I (W/m²) at the location P at a distance d (m) in the vertical direction from the linear sound source 310 is expressed by the following equation (4):

$$I = \frac{{W}_{m}}{4 π } \cdot \frac{a}{d} ( W / {m}^{2} ) \qquad ( 4 )$$

where Wₘ (W) represents the power per unit length of the linear sound source, and α (radian) represents the angle of the sound receiving point with respect to both ends of the linear sound source. As shown by the equation, the sound intensity generated from the linear sound source is proportional to the angle α, and is inversely proportional to the distance d in the vertical direction.

In the case of a linear sound source with an infinite length, α=π holds, and if α=π is assigned to the equation (4), the sound pressure level Lₚ is expressed by the following equation (5):
Lₚ=L_{Wm}−10 log₁₀ d−6 (dB) (5)

When the linear sound source has a finite length 1, if the distance d from the linear sound source to the sound receiving point becomes longer and if α can approximate 1/d, the sound pressure level Lₚ is expressed by the following equation (6):
Lₚ=L_{Wm}−20 log₁₀ d−11 (dB) (6)

Accordingly, while the distance d is shorter than 1/π, the sound pressure level drops by approximately 3 dB (10×log₁₀2) when the distance is doubled. Once the distance d exceeds 1/π, the sound pressure level drops by approximately 6 dB when the distance is doubled. This relationship is shown by the graph in FIG. 3B. The relationship between the logarithm of the distance d and the sound pressure level is represented by a curve 301. However, when the distance d is shorter than 1/π, an approximation to the attenuation characteristics of the linear sound source indicated by a straight line 302 holds. When the distance d is longer than 1/π, an approximation to the attenuation characteristics of the point sound source indicated by a straight line 303 holds.

As described above, the sound intensity of the linear sound source characteristically decreases in inverse proportion to the distance to the sound receiving point in principle. However, when the distance to the sound receiving point is long, the linear sound source is approximated by the point sound source, and the sound intensity generated from the linear sound source exhibits the characteristics of decreasing in inverse proportion to the square of the distance to the sound receiving point.

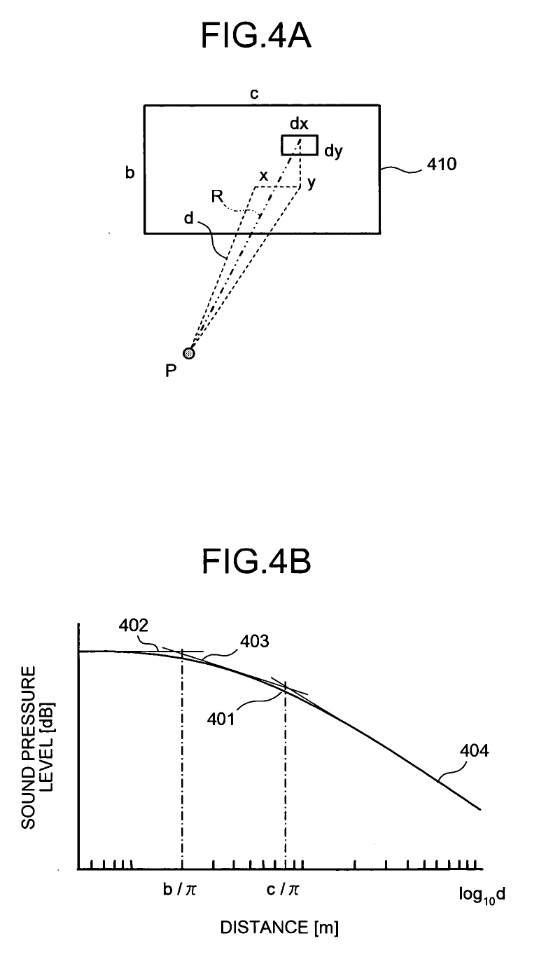

FIGS. 4A and 4B show the sound pressure level in relation to the distance from a plane sound source. As shown in FIG. 4A, an area element of height dy (m) and width dx (m) is included in a plane sound source 410 of height b (m) and width c (m). The description below is based on the premise that the width of the plane sound source is greater than the height of the plane sound source (c>b). In FIG. 4A, R represents the distance (m) from the area element to a sound receiving point P, and x, y, and d represent the components of R in the width direction, the height direction, and the vertical direction of the plane sound source, respectively.

At the sound receiving point P, the sound intensity Iᵤ (W/m²) output from the above mentioned area element is expressed by the following equation (7):

$$Iu = ( \frac{W}{b \cdot c} ) \frac{dx \cdot dy}{4 π {R}^{2}} ( W / {m}^{2} ) \qquad ( 7 )$$

where W represents the total power (W) of the plane sound source. Accordingly, at the sound receiving point P, the sound intensity I (W/m²) output from all the area elements of the plane sound source 410 is expressed by the following equation (8):

$$I = 2 {\int }_{x = 0}^{\frac{c}{2}} {\int }_{y = 0}^{\frac{b}{2}} ( \frac{W}{b \cdot c} ) \frac{dx \cdot dy}{4 π {R}^{2}} ( W / {m}^{2} ) \qquad ( 8 )$$

As a modification of the equation (8), the following equation (9) is obtained:

$$I = \frac{W}{π bc } \cdot arc tg \frac{c}{2 d} \cdot arc tg \frac{b}{2 d} ( W / {m}^{2} ) \qquad ( 9 )$$

When the vertical distance d from the sound receiving point to the plane sound source 410 is smaller than the height b and the width c of the plane sound source 410 in a region (hereinafter referred to as the first region) in which the vertical distance d to the sound receiving point is shorter than b/π, an approximation holds as shown in the following expression (10):

$$arc tg \frac{c}{2 d} \approx \frac{π}{2} , arc tg \frac{b}{2 d} \approx \frac{π}{2} \qquad ( 10 )$$

Accordingly, the sound intensity I (W/m²) at the sound receiving point P is expressed by the following equation (11):

$$I = \frac{W}{π bc} \cdot \frac{π}{2} \cdot \frac{π}{2} = \frac{W π}{4 bc} ( W / {m}^{2} ) \qquad ( 11 )$$

As shown above, in the first region, the sound intensity I at the sound receiving point P is constant, and does not depend on the distance d from the sound source. This is the characteristics of a typical plane sound source.

When the vertical distance d from the sound receiving point to the plane sound source 410 is greater than the height b but is smaller than the width c of the plane sound source 410 in a region Thereinafter referred to as the second region) in which the vertical distance d to the sound receiving point is longer than b/π and shorter than c/π, an approximation holds as shown in the following expression (12):

$$arc tg \frac{c}{2 d} \approx \frac{π}{2} , arc tg \frac{b}{2 d} \approx \frac{b}{2 d} \qquad ( 12 )$$

Accordingly, the sound intensity I (W/m²) at the sound receiving point P is expressed by the following equation (13):

$$I = \frac{W}{π bc} \cdot \frac{π}{2} \cdot \frac{b}{2 d} = \frac{W }{4 c d} ( W / {m}^{2} ) \qquad ( 13 )$$

As shown above, in the second region, the sound intensity I at the sound receiving point P is inversely proportional to the distance d from the sound source, which represents the same characteristics as the characteristics of the linear sound source.

In a region (hereinafter referred to as the third region) in which the vertical distance d from the sound receiving point to the plane sound source 410 is greater than c/π, an approximation holds as shown in the following expression (14):

$$arc tg \frac{c}{2 d} \approx \frac{c}{2 d} , arc tg \frac{b}{2 d} \approx \frac{b}{2 d} \qquad ( 14 )$$

Accordingly, the sound intensity I (W/m²) at the sound receiving point P is expressed by the following equation (15):

$$I = \frac{W}{π bc} \cdot \frac{c}{2 d} \cdot \frac{b}{2 d} = \frac{W}{4 π {d}^{2}} ( W / {m}^{2} ) \qquad ( 15 )$$

As shown above, in the third region, the sound intensity I at the sound receiving point P is inversely proportional to the square of the distance d from the sound source, which represents the same characteristics as the characteristics of the point sound source.

The graph in FIG. 4B shows the characteristics of the plane sound source in the above described respective regions. The relationship between the logarithm of the distance d and the sound pressure level of the plane sound source 410 is indicated by a curve 401. However, it can be approximated by a straight line 402 indicating the sound pressure level that does not depend on the distance in the first region, a straight line 403 indicating the same characteristics as the characteristics of the linear sound source in the second region, and a straight line 404 indicating the same characteristics as the characteristics of the point sound source in the third region.

As described above, the sound intensity of the plane sound source does not decrease irrespective of the distance to the sound receiving point, when the sound receiving point is close to the sound source. However, when the distance to the sound receiving point is long, the sound intensity of the plane sound source is approximated by that of the linear sound source or the point sound source in accordance with the distance, and the plane sound source exhibits the attenuation characteristics of the linear sound source or the point sound source.

Although the general characteristics of each type of sound source have been described so far in terms of sound intensity, the following is a description of the characteristics of each sound source in terms of sound pressure, especially the distance decay rate that represents the ratio of a decrease in sound pressure to the distance.

As described above, the sound intensity of the point sound source is inversely proportional to the square of the distance, the-sound intensity of the linear sound source is inversely proportional to the distance, and the sound intensity of the plane sound source is constant regardless of the distance. Further, the sound intensity is generally proportional to the square of sound pressure. As is apparent from those facts, the distance decay rate of the point sound source is 1/r, the distance decay rate of the linear sound source is 1/vr, and the distance decay rate of the plane sound source is 1. Here, r represents the distance from each sound source.

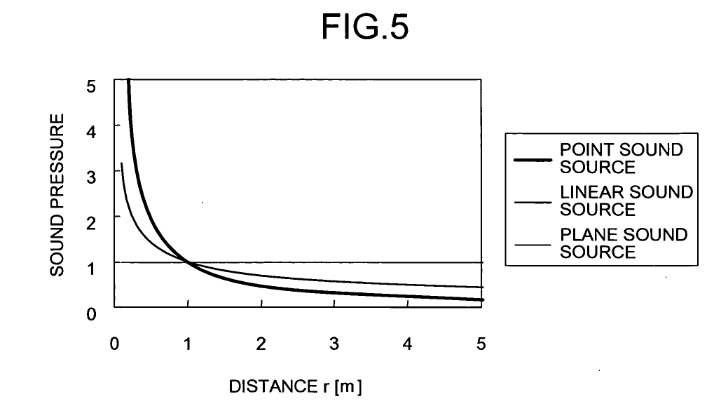

FIG. 5 shows the sound pressure of sound at the receiving point that is located at a distance r (m) from each sound source. In FIG. 5, an exemplary case is shown where the sound pressures of the sounds output from the respective sound sources become equal to one another at the sound receiving point located at the distance of 1 m.

As shown in FIG. 5, the sound output from the plane sound source does not depend on the distance, and the sound pressure of the plane sound source is constant. On the other hand, the sound pressure of the sound output from the linear sound source rapidly drops within the range of 1 m from the sound source, and slowly decreases beyond the 1 m range. The sound pressure of the sound output from the point sound source decreases very rapidly near the sound source, and keeps decreasing beyond the 1 m range.

Taking advantage of the differences in distance decay rate among sound sources, region dividing can be performed. In doing so, the active noise reduction method is utilized to reduce the sound through interference caused by an additional sound source that outputs sound of the opposite phase to the phase of the sound of the main sound source. In the following, the operation is described in detail.

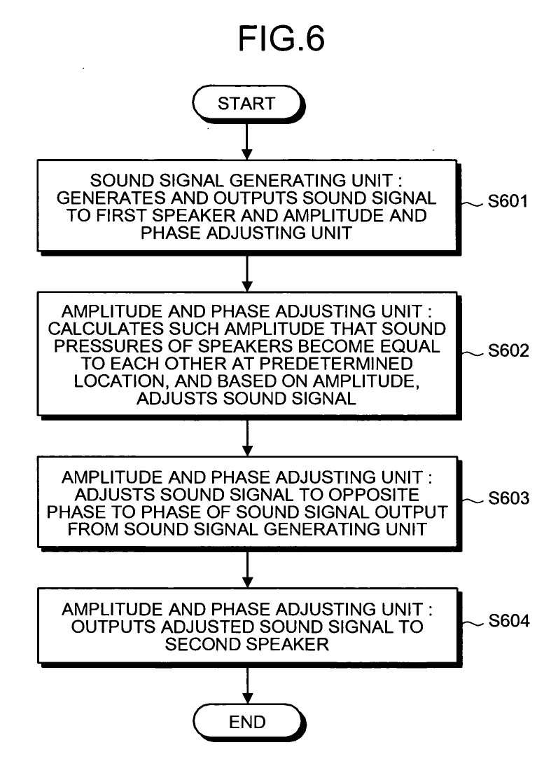

FIG. 6 is a flowchart of the amplitude and phase adjusting operation to be performed by the sound reproducing apparatus 100 in accordance with the first embodiment.

First, the sound signal generating unit 111 generates a first sound signal based on a source sound signal reproduced by the content reproducing unit 101, and then supplies the first sound signal to the first speaker 121 that is the main sound source. In other words, the sound signal generating unit 111 supplies the first sound signal directly to the first speaker 121. Further, the sound signal generating unit 111 supplies the same signal as the first sound signal to the amplitude and phase adjusting unit 112 (step S601). Here, any method employed for general sound reproducing apparatuses can be used as the method of reproducing contents by the content reproducing unit 101 and the method of generating the first sound signal from a reproduced source sound signal and supplying the first sound signal to the speaker.

Next, the amplitude and phase adjusting unit 112 calculates the amplitude of a second sound signal so that the sound pressures of the sounds output from the respective speakers 121 and 122 are equal at a predetermined distance, for example, 4 m, when the sound is output from the second speaker 122 that is an additional sound source with a different distance decay rate from that of the first speaker 121. Based on the calculated amplitude, the amplitude and phase adjusting unit 112 adjusts the second sound signal to be supplied to the second speaker 122 (step S602). Since the distance decay rate of each speaker takes a known value, the amplitude and phase adjusting unit 112 can calculate the amplitude of the second sound signal so that the sound pressures become equal to each other, as long as the appropriate distance for matching the sound pressures is given.

The amplitude and phase adjusting unit 112 then adjusts the phase of the second sound signal to be supplied to the second speaker 122, so that the phase of the second sound signal becomes opposite to the phase of the first sound signal generated by the sound signal generating unit 111 (step S603). By doing so, sound reduction can be achieved through interference between the sound output from the first speaker 121 and the sound output from the second speaker 122.

The amplitude and phase adjusting unit 112 then supplies the second sound signal, which has been adjusted in terms of amplitude and phase, to the second speaker 122 (step S604). In this manner, the first sound signal generated by the sound signal generating unit 111 is output from the first speaker 121, and the second sound signal adjusted in terms of amplitude and phase by the amplitude and phase adjusting unit 112 is output from the second speaker 122.

In the vicinity of each speaker, the sound output from each speaker remains even after the interference with the sound of the opposite phase, because the difference in amplitude is large due to the difference in attenuation. Thus, a non-reduction region is formed near the sound sources.

Beyond a predetermined range from the sound sources, the sound pressures of the sounds output from the speakers drop to substantially the same values as each other. Accordingly, sound reduction can be performed through interference between sounds of opposite phases, and a reduction region can be formed. Since the first speaker 121 as the main sound source and the second speaker 122 as the additional sound source output sounds from the same location in the same direction, the region dividing can be performed even in a sound source layout of a concentrated type.

Where the region dividing is performed with two sound sources having different distance decay rates, the main sound source and the additional sound source may be a point sound source and a linear sound source (or vice versa), a point sound source and a plane sound source (or vice versa), or a linear sound source and a plane sound source (or vice versa).

The combinations of the main sound source and the additional sound source are not limited to the above, and any combination of sound sources may be employed, as long as the sound sources have different distance decay rates. For example, a sound source having a distance decay rate in the middle of that of the point sound source and that of the linear sound source can be formed by adjusting the number and the locations of point sound sources, and the region dividing can be performed with a combination of such sound sources.

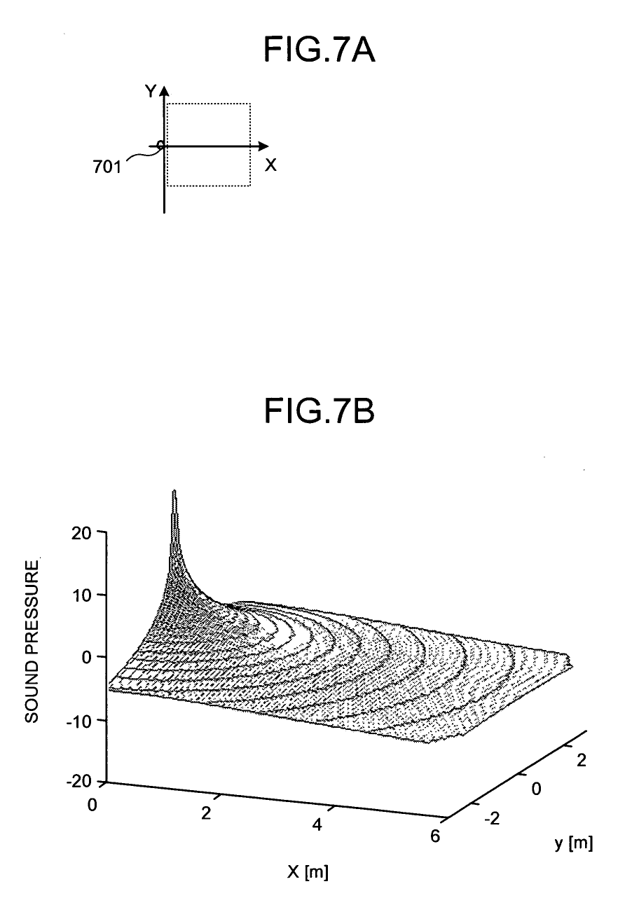

FIGS. 7 through 10 show the variations of distance decay rates in cases where the number of point sound sources is varied. More specifically, FIGS. 7A and 7B show the distribution of sound pressure on an XY plane in a case where the number of point sound sources is one. In FIG. 7B, the distribution of sound pressure is represented in the form of three-dimensional space coordinates, with the ordinate axis indicating the sound pressure. Since a point sound source 701 is located at the point of origin of the three-dimensional space coordinates, as shown in FIG. 7A, the sound pressure of the sound output from the point sound source 701 varies with the location of the sound receiving point as indicated by the graph in FIG. 7B.

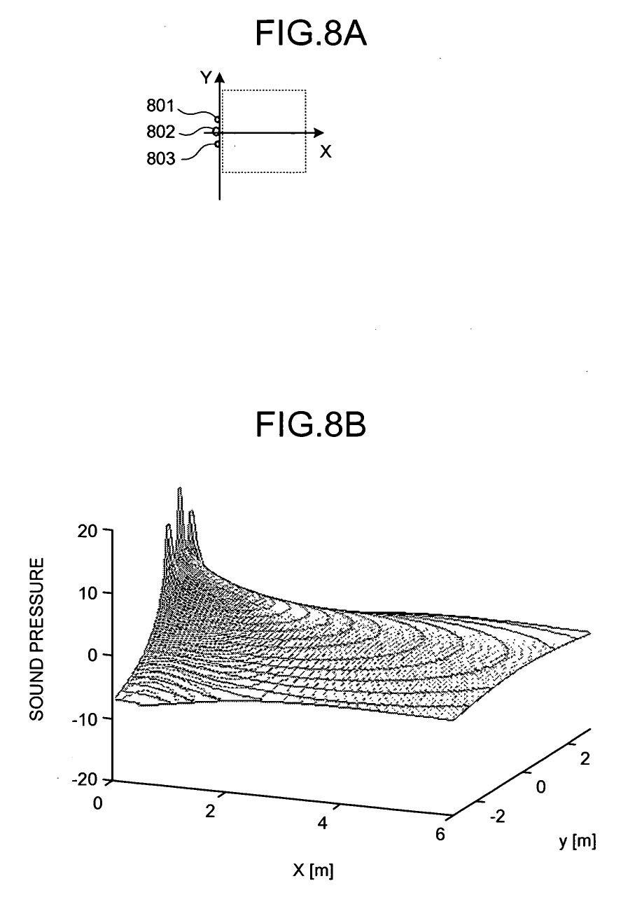

FIGS. 8A and 8B show the distribution of sound pressure on an XY plane in a case where the number of point sound sources is three. In FIG. 8B, the distribution of sound pressure is represented in the form of three-dimensional space coordinates, with the ordinate axis indicating the sound pressure. Since a point sound source 802 is located at the point of origin of the three-dimensional space coordinates and point sound sources 801 and 803 are located on the Y axis so as to sandwich the point sound source 802, as shown in FIG. 8A, the synthesis sound pressure of the sounds output from the point sound sources 801 through 803 varies as indicated by the graph in FIG. 8B.

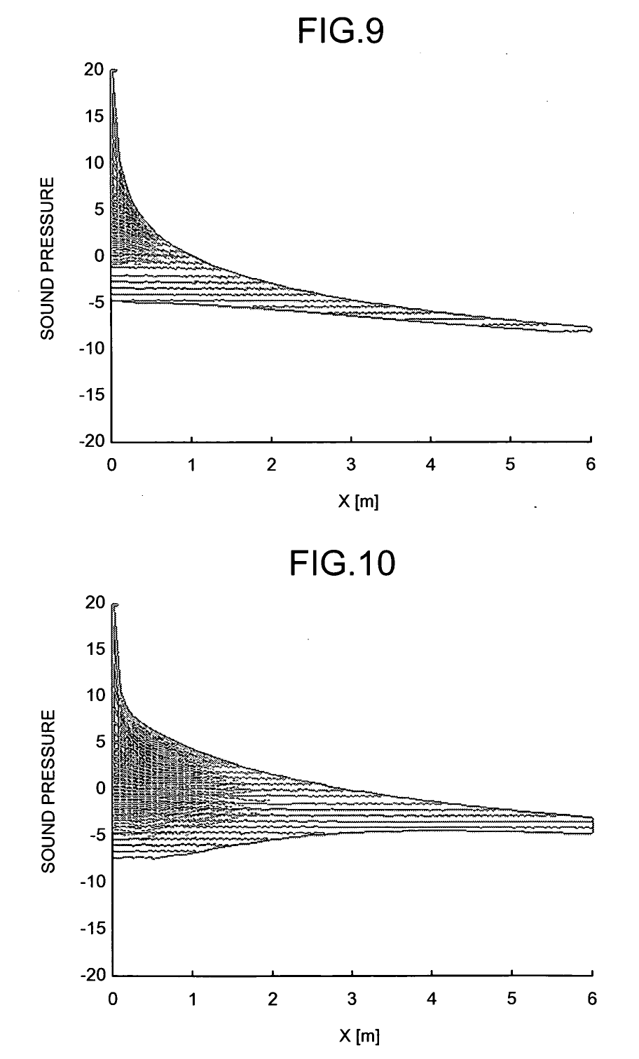

FIGS. 9 and 10 show the sound pressure distributions shown in FIGS. 7 and 8 in the form of two-dimensional coordinates, with the Y axis being the visual axis. As shown in FIGS. 9 and 10, the sound pressure gradient (which is the attenuation gradient) is gentler in the case of three point sound sources than in the case of one point sound source. As the number of point sound sources increases, the sound pressure gradient becomes even gentler and approximates the sound pressure gradient of a linear sound source. This proves that the linear sound source can be realized by a group of point sound sources. Likewise, the plane sound source can be realized by a group of point sound sources.

Accordingly, where the distance decay rate is expressed as 1/rⁿ, the value n varies as 1, 0.5, and 0 for the cases of the point sound source, the linear sound source, and the plane sound source, respectively. However, the value n is not limited to those three values. The number and the locations of point sound sources may be adjusted so as to generate a distance decay rate with any value n in the range of 1 to 0. In this manner, two sound sources having different distance decay rates from each other can be combined, and region dividing can be performed in the above described manner.

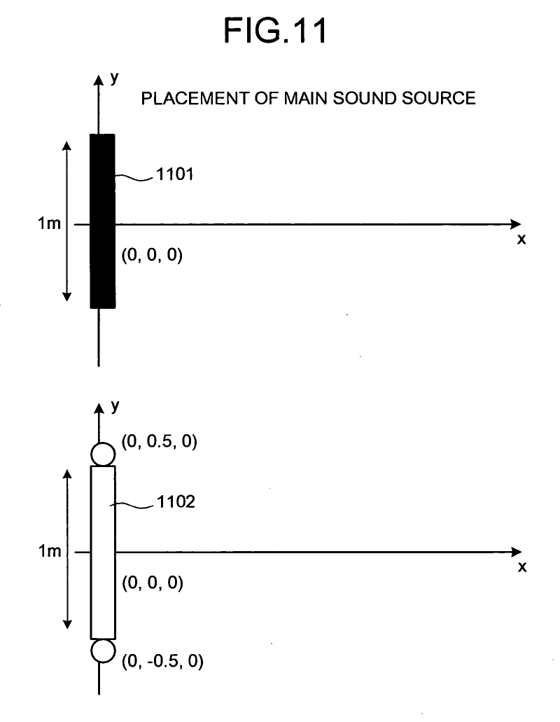

FIGS. 11 through 15 show the results of simulations where region dividing is performed through the combination of a main sound source having the characteristics of the linear sound source and an additional sound source having the combined characteristics of the point sound source and the linear sound source.

FIG. 11 shows the layout of the main sound source and the additional sound source. As shown in the upper part of FIG. 11, a main sound source 1101 is a linear sound source having a width of 1 m extending along the Y axis, with the point of origin of three-dimensional space coordinates being the center of the linear sound source. As shown in the lower part of FIG. 11, an additional sound source 1102 is formed with a linear sound source and two point sound sources provided at both ends of the linear sound source. The linear sound source has a width of 1 m extending along the Y axis, with the point of origin of the three-dimensional space coordinates being its center.

FIG. 12 shows the main sound source and the additional sound source in relation to such a distance as to minimize the synthesis sound pressure. As shown in FIG. 12, the main sound source 1101 and the additional sound source 1102 overlap each other, with the center of each sound source being located at the point of origin of the three-dimensional space coordinates. Here, the synthesis sound pressure of the sounds output from the sound sources is minimized at a location 1201 on the X axis at a distance of 8 m from the point of origin.

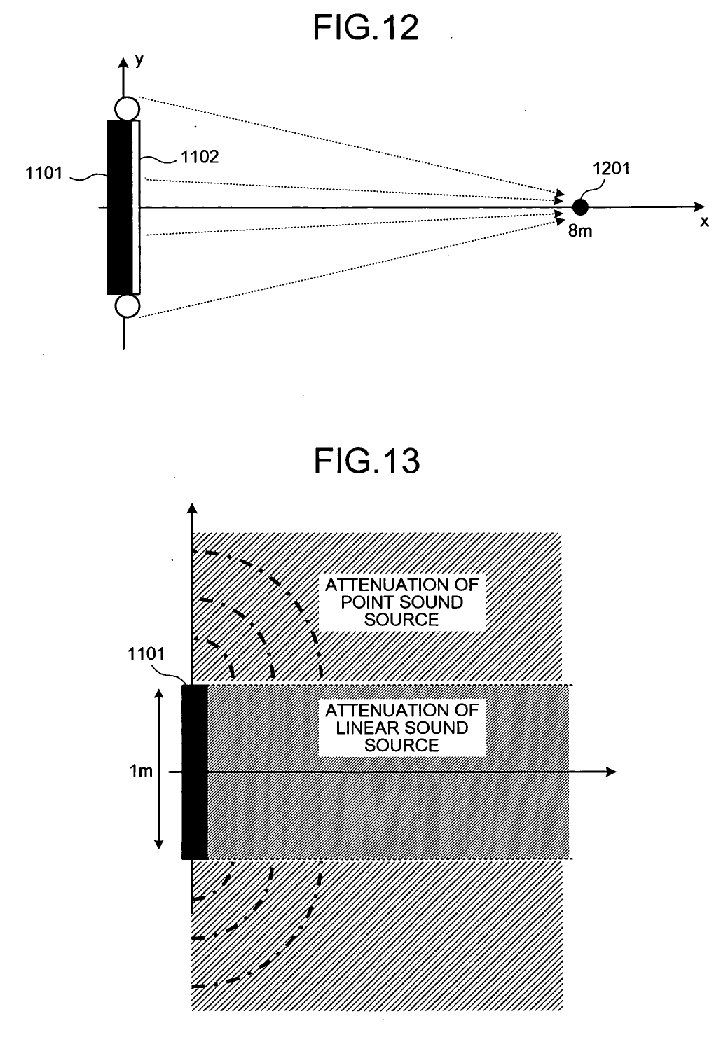

FIG. 13 shows the characteristics of the sound sources that are used as the basis of a simulation. As shown in FIG. 13, the main sound source 1101 presumably exhibits the attenuation characteristics of the linear sound source in a direction perpendicular to the sound source, and exhibits the attenuation characteristics of the point sound source in the regions on both sides. Although not shown in FIG. 13, the linear sound source part of the additional sound source 1102 also presumably exhibits the same attenuation characteristics as the above.

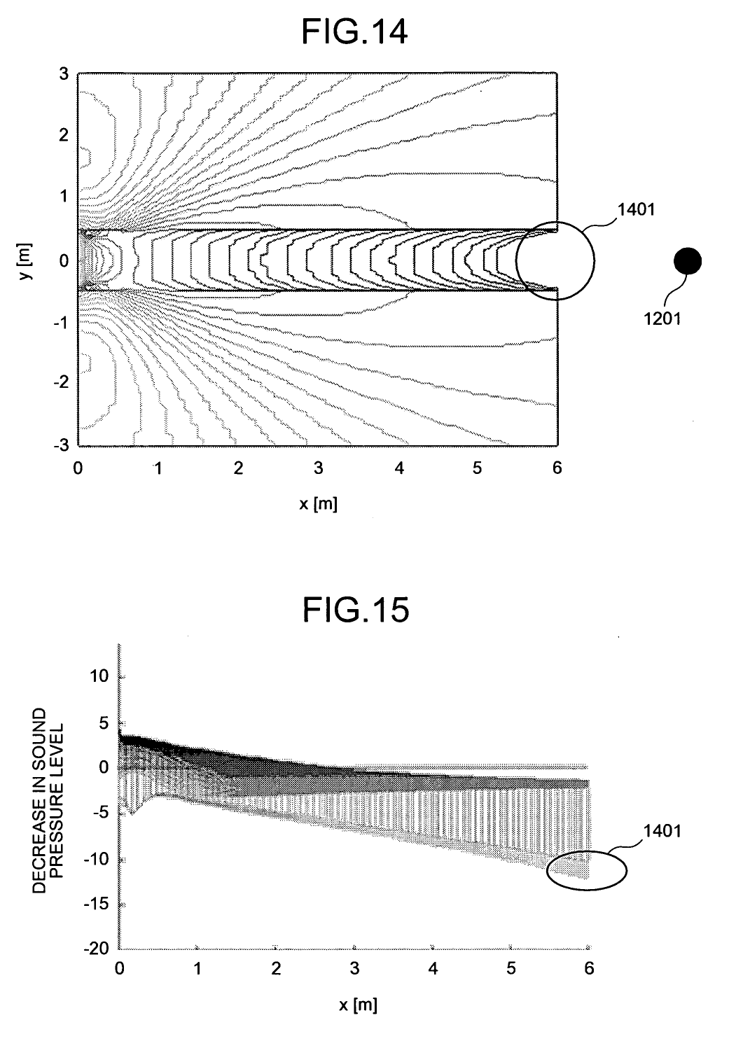

FIGS. 14 and 15 show the decrease in sound pressure level of the above sound sources in a case where region dividing is performed in the above described manner. Here, the “decrease in sound pressure level” is the difference in sound pressure level between before and after the control. More specifically, the decrease in sound pressure level is obtained by subtracting the sound pressure level (dB) of the sound output only from the main sound source, from the sound pressure level (dB) obtained in the case where the control sound for reducing the sound output from the main sound source is output from the additional sound source for the region dividing. Accordingly, a larger decrease in sound pressure level means a greater sound reducing effect.

In FIG. 14, decreases in sound pressure level at various locations on the two-dimensional coordinates are represented by contour lines, with the X axis being the traveling direction of sound, and with the sound source being the point of origin of the two-dimensional coordinates. As can be seen from the contour lines, the decrease in sound pressure level is larger at a longer distance from the sound source. In FIG. 14, a 10 dB decrease in sound pressure is observed at a location 1401 that is approximately 6 m away from the sound source and is located before the location 1201 at which the synthesis sound pressure is minimized.

FIG. 15 schematically shows the decrease in sound pressure level in relation to the distance x (m) from the sound sources, with the Z axis indicating the decrease in sound pressure level, and with the Y axis being the visual axis. As shown in FIG. 15, a −10 dB decrease in sound pressure level is observed at the location 1401 that is approximately 6 m away from the sound source. Further, it can be seen that the sound remains without a decrease near the sound sources.

As described so far, in the sound reproducing apparatus 100 in accordance with the first embodiment, two speakers that are arranged to output sounds from substantially the same points in substantially the same directions and have different distance decay rates from each other output such sounds as to restrain the synthesis sound pressure of the sounds output from the speakers at a predetermined location. Accordingly, the sound field can be divided into a non-reduction region and a reduction region, with the predetermined location serving as the boundary. In this manner, region dividing can be performed even in such a speaker layout as an integrated type layout in which freedom is not allowed in the arrangement of the main sound source and the additional sound source.

In a sound reproducing apparatus in accordance with a second embodiment of the present invention, the synthesis sound pressure of sounds output from two speakers at a predetermined location is detected, and based on the detected synthesis sound pressure, the amplitude and the phase of a sound signal are determined so as to restrain the synthesis sound pressure of the sounds output from the two speakers at the predetermined location.

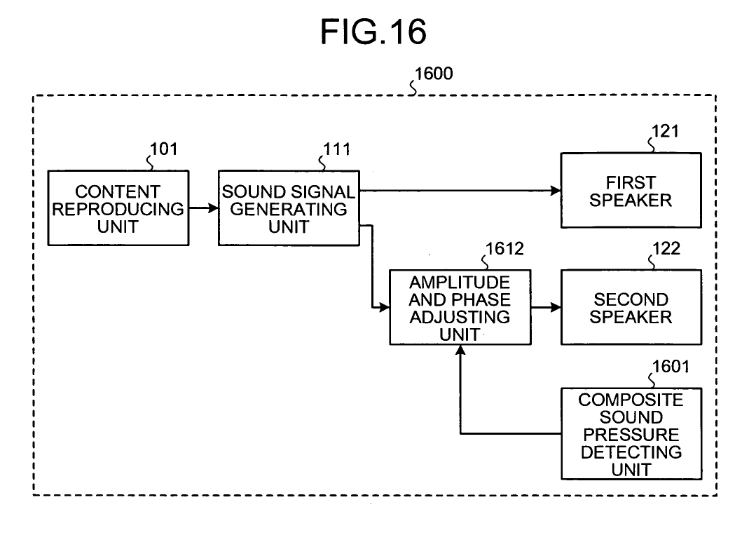

FIG. 16 is a block diagram of the structure of a sound reproducing apparatus 1600 in accordance with the second embodiment. As shown in FIG. 16, the sound reproducing apparatus 1600 includes a content reproducing unit 101, a sound signal generating unit 111, an amplitude and phase adjusting unit 1612, a synthesis sound pressure detecting unit 1601, a first speaker 121, and a second speaker 122.

The second embodiment differs from the first embodiment in that the synthesis sound pressure detecting unit 1601 is added and the amplitude and phase adjusting unit 1612 has different functions from the functions of the amplitude and phase adjusting unit 112. The other aspects of the structure and functions in accordance with the second embodiment are the same as those of the structure and functions of the sound reproducing apparatus 100 in accordance with the first embodiment shown in the block diagram of FIG. 1. Therefore, like components are denoted by like reference characters and explanation of those components is not repeated in the following description.

The synthesis sound pressure detecting unit 1601 detects the synthesis sound pressure that is generated by combining the sound pressure of the sound output from the first speaker 121 and the sound pressure,of the sound output from the second speaker 122 at a predetermined distance. The detected synthesis sound pressure is output to the amplitude and phase adjusting unit 1612.

Based on the synthesis sound pressure detected by the synthesis sound pressure detecting unit 1601, the amplitude and phase adjusting unit 1612 adjusts the amplitude and the phase of a first sound signal output from the sound signal generating unit 111, so as to restrain the synthesis sound pressure that is generated by combining the sound pressures of the first speaker 121 and the second speaker 122 at the predetermined distance. The sound signal having the adjusted amplitude and the adjusted phase is supplied as a second sound signal to the second speaker 122.

More specifically, the amplitude and phase adjusting unit 1612 performs a feedback control operation, based on the synthesis sound pressure detected by the synthesis sound pressure detecting unit 1601. By doing so, the amplitude and phase adjusting unit 1612 adjusts the amplitude and the phase of the first sound signal to be output from the first speaker 121 and the amplitude and the phase of the second sound signal to be output from the second speaker 122, so that the synthesis sound pressure detected by the synthesis sound pressure detecting unit 1601 becomes 0, which is the target value of the synthesis sound pressure. Here, any feedback controlling method that is generally used can be employed.

As described above, the sound reproducing apparatus 1600 in accordance with the second embodiment differs from the sound reproducing apparatus 100 in accordance with the first embodiment in that the synthesis sound pressure detected by the synthesis sound pressure detecting unit 1601 is fed back for the amplitude and phase adjustment, so that the amplitude and phase adjusting unit 1612 can perform an optimum amplitude and phase adjusting operation.

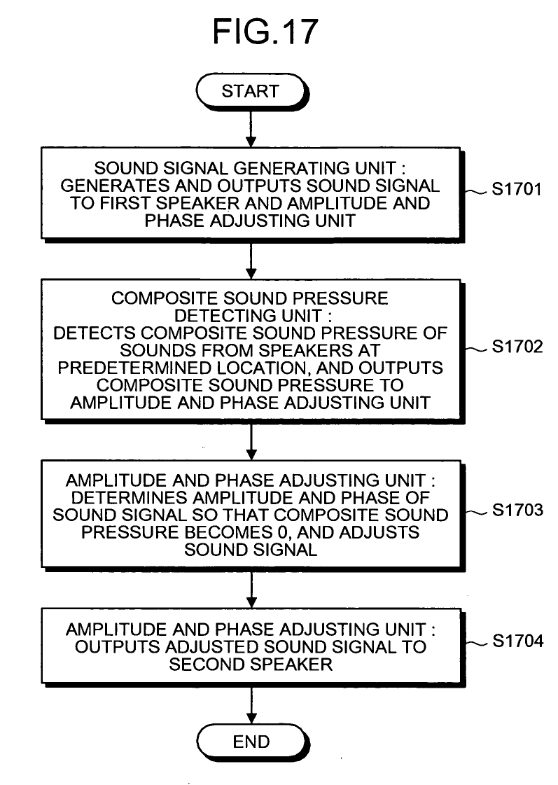

FIG. 17 is a flowchart of the amplitude and phase adjusting operation in the sound reproducing apparatus 1600 in accordance with the second embodiment.

First, the sound signal generating unit 111 generates a first sound signal based on a source sound signal reproduced by the content reproducing unit 101, and supplies the first sound signal to the first speaker 121 which serves as the main sound source and to the amplitude and phase adjusting unit 1612 (step S1701).

Next, the synthesis sound pressure detecting unit 1601 detects the synthesis sound pressure which is a combination of the sound pressure of the sound output from the first speaker 121 and the sound pressure of the sound output from the second speaker 122 at a predetermined location. The synthesis sound pressure detecting unit 1601 then supplies the synthesis sound pressure to the amplitude and phase adjusting unit 1612 (step S1702).

The amplitude and phase adjusting unit 1612 then adjusts the amplitude and the phase of a second sound signal to be output to the second speaker 122 using the synthesis sound pressure detected by the synthesis sound pressure detecting unit 1601 as a feedback signal, so that actual synthesis sound pressure becomes zero (step S1703).

The amplitude and phase adjusting unit 1612 then supplies the second sound signal having the adjusted amplitude and the adjusted phase to the second speaker 122 (step S1704). In this manner, the first sound signal generated by the sound signal generating unit 111 is output from the first speaker 121, and the second sound signal having the amplitude and the phase adjusted by the amplitude and phase adjusting unit 1612 is output from the second speaker 122.

As described above, in the sound reproducing apparatus 1600 in accordance with the second embodiment, the synthesis sound pressure of the sounds output from two speakers at a predetermined location is detected. Based on the detected synthesis sound pressure that is fed back for the amplitude and phase adjustment, the amplitude and the phase of a sound signal are optimized so as to restrain the synthesis sound pressure of the sounds output from the two speakers at the predetermined location. In this manner, region dividing can be performed even in such a speaker layout as an integrated type layout in which freedom is not allowed in the arrangement of the main sound source and the additional sound source.

In a sound reproducing apparatus in accordance with a third embodiment of the present invention, region dividing is performed, with the main sound source and the additional sound source being selected from speakers that are arranged in a matrix fashion. The selected two speakers should have different distance decay rates from each other. Hereinafter, speakers arranged in a matrix fashion will be referred to as a “matrix speaker”, and the individual speakers that constitute the matrix speaker will be referred to as “element speakers.”

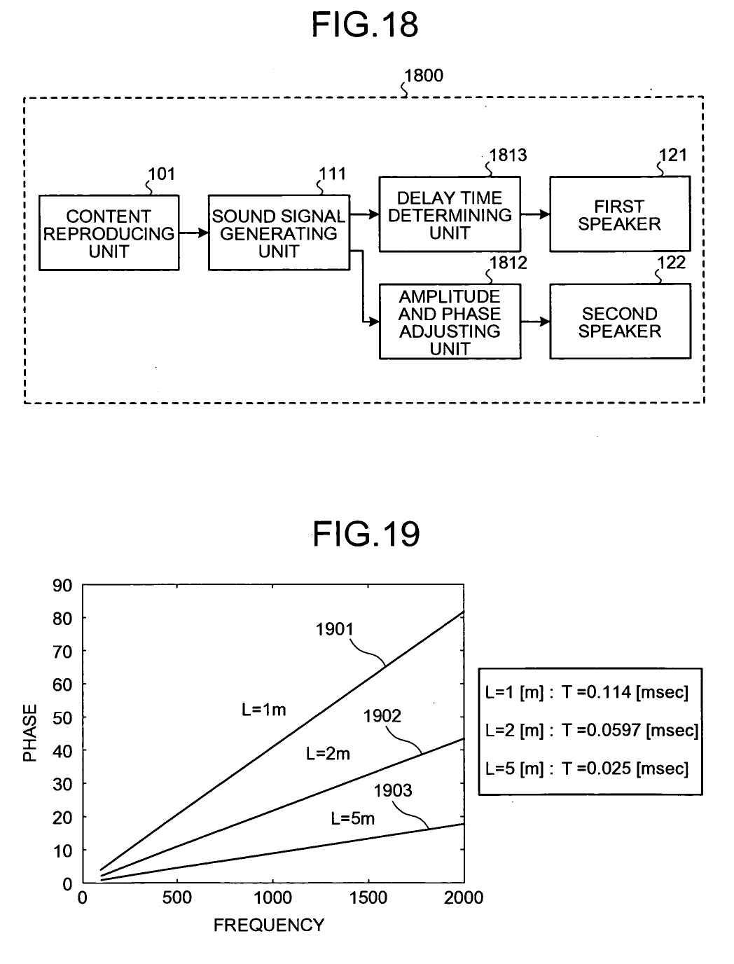

FIG. 18 is a block diagram of the structure of a sound reproducing apparatus 1800 in accordance with the third embodiment. As shown in FIG. 18, the sound reproducing apparatus 1800 includes a content reproducing unit 101, a sound signal generating unit 111, an amplitude and phase adjusting unit 1812, a delay time determining unit 1813, a first speaker 121, and a second speaker 122.

The third embodiment differs from the first embodiment in that the delay time determining unit 1813 is added, and the amplitude and phase adjusting unit 1812 has different functions from the functions of the amplitude and phase adjusting unit 112. The other aspects of the structure and functions of the third embodiment are the same as those of the sound reproducing apparatus 100 in accordance with the first embodiment shown in the block diagram of FIG. 1. Therefore, like components are denoted by like reference characters and explanation of those components is not repeated herein.

In the sound reproducing apparatus 1800 in accordance with the third embodiment, element speakers of a given size and a given shape constitute a matrix speaker, and a given number of speakers at a given location are selected as the first speaker 121 or the second speaker 122. Here, the selection should be made so that the first speaker 121 and the second speaker 122 have different distance decay rates from each other.

The delay time determining unit 1813 determines a delay time between the sounds to be output to the speakers, so as to restrain the synthesis sound pressure of the sounds output from the first speaker 121 and the second speaker 122 at a predetermined location. The method of calculating the delay time will be described later. The delay time determining unit 1813 delays a first sound signal output from the sound signal generating unit 111 by the determined delay time, and supplies the delayed first sound signal as a second sound signal to the first speaker 121.

When M of element speakers are selected as the first speaker 121 from the matrix speaker, and N of element speakers are selected as the second speaker 122 from the matrix speaker, the amplitude and phase adjusting unit 1812 sets the amplitude of a third sound signal to be supplied to the second speaker 122 to a value M/N times as high as the amplitude of the first sound signal output from the sound signal generating unit 111, and sets the phase of the third sound signal to the opposite of the phase of the first sound signal, so as to restrain the synthesis sound pressure of the sounds output from the respective speakers. The reasons for the settings are as follows.

When the speakers are point sound sources, the sound pressure P at a distance r (m) from the sound source can be expressed as P=Z·q, where q represents the complex amplitude, and Z represents the radiation impedance. Here, the complex amplitude q and the radiation impedance Z are expressed by the following equations (16):

$$q = \vert q \vert {ⅇ}^{jθ} , Z = \frac{ρjω}{4 π r} {ⅇ}^{- j kr} \qquad ( 16 )$$

When the complex amplitude qₚ of the first speaker 121 (the main sound source), the complex amplitude qₛ of the second speaker 122 (the additional sound source), the radiation impedance Zₚᵢ between each element speaker constituting the first speaker 121 and the sound receiving point R, and the radiation impedance Zₛᵢ between each element speaker constituting the second speaker 122 and the sound receiving point R are expressed by the following equations (17) through (20), the decrease η in sound pressure level is expressed by the equation (21):

$$\begin{matrix}{q}_{p} = \vert {q}_{p} \vert {ⅇ}^{{jθ}_{p}} & ( 17 ) \\ {q}_{s} = \vert {q}_{s} \vert {ⅇ}^{{jθ}_{s}} & ( 18 ) \\ {Z}_{pi} = \frac{ρjω}{4 π {r}_{pi}} {ⅇ}^{- j {kr}_{pi}} & ( 19 )\end{matrix}$$

(where rₚᵢ(1≦i≦M) represents the distance between each main sound source and the sound receiving point R)

$${Z}_{si} = \frac{ρjω}{4 π {r}_{si}} {ⅇ}^{- j {kr}_{si}} \qquad ( 20 )$$

(where rₛᵢ(1≦i≦N) represents the distance between each additional sound source and the sound receiving point R)

$$\begin{matrix}η = 20 log \vert \frac{{\sum }_{i = 1}^{M} {Z}_{pi} {q}_{p} + {\sum }_{i = 1}^{N} {Z}_{si} {q}_{s}}{{\sum }_{i = 1}^{M} {Z}_{pi} {q}_{p}} \vert \\ = 20 log \vert 1 + \frac{\vert {q}_{s} \vert {ⅇ}^{{jθ}_{s}}}{\vert {q}_{p} \vert {ⅇ}^{{jθ}_{p}}} \cdot \frac{{\sum }_{i = 1}^{N} \frac{cos {kr}_{si}}{{r}_{si}} + j ( - {\sum }_{i = 1}^{N} \frac{sin {kr}_{si}}{{r}_{si}} )}{{\sum }_{i = 1}^{M} \frac{cos {kr}_{pi}}{{r}_{pi}} + j ( - {\sum }_{i = 1}^{M} \frac{sin {kr}_{pi}}{{r}_{pi}} )} \vert\end{matrix} \qquad ( 21 )$$

If the sound receiving point is located far away from the sound sources, the distances from the sound sources to the sound receiving point R can be regarded as uniform, and the relationship can be expressed as rₚ=rₛ=r. Accordingly, the decrease q in sound pressure level can be expressed by the following modified equation (22):

$$\begin{matrix}η = 20 log \vert 1 + \frac{\vert {q}_{s} \vert {ⅇ}^{{jθ}_{s}}}{\vert {q}_{p} \vert {ⅇ}^{{jθ}_{p}}} \cdot \frac{{\sum }_{i = 1}^{N} \frac{cos kr}{r} + j ( - {\sum }_{i = 1}^{N} \frac{sin kr}{r} )}{{\sum }_{i = 1}^{M} \frac{cos kr}{r} + j ( - {\sum }_{i = 1}^{M} \frac{sin kr}{r} )} \vert \\ = 20 log \vert 1 + \frac{\vert {q}_{s} \vert {ⅇ}^{{jθ}_{s}}}{\vert {q}_{p} \vert {ⅇ}^{{jθ}_{p}}} \cdot \frac{N}{M} \vert\end{matrix} \qquad ( 22 )$$

In accordance with this equation (22), the amplitude and the phase to restrain the synthesis sound pressure of the sound output from the first speaker 121 and the sound output from the second speaker 122, in other words, the amplitude and the phase to maximize the decrease in sound pressure level, can be determined. Since the decrease η in sound pressure level increases (more precisely, the absolute value of the decrease η in sound pressure level increases) as the value in the absolute value brackets in the equation (22) approaches zero, the amplitude |qₛ| and the phase θₛ should be calculated to satisfy the following equation (23):

$$1 + \frac{\vert {q}_{s} \vert {ⅇ}^{{jθ}_{s}}}{\vert {q}_{p} \vert {ⅇ}^{{jθ}_{p}}} \cdot \frac{N}{M} = 0 \qquad ( 23 )$$

The amplitude |qₛ| and the phase θₛ to satisfy the above conditions are expressed by the following equation (24), and when the amplitude |qₛ| and the phase θₛ are assigned to the equation (18), the complex amplitude of the second speaker 122 as the additional sound source is expressed by the equation (25):

$$\begin{matrix}\vert {q}_{s} \vert = \frac{M}{N} \vert {q}_{p} \vert , {θ}_{s} = {θ}_{p} + π & ( 24 ) \\ {q}_{s} = \frac{M}{N} \vert {q}_{p} \vert \cdot {ⅇ}^{j ( {θ}_{p} + π )} = - \frac{M}{N} \vert {q}_{p} \vert \cdot {ⅇ}^{{jθ}_{p}} & ( 25 )\end{matrix}$$

As described above, the amplitude and phase adjusting unit 1812 may set the amplitude of the third sound signal to be supplied to the second speaker 122 to a value that is M/N times as high as the amplitude of the first sound signal supplied from the sound signal generating unit 111, and also sets the phase of the third sound signal to the opposite of the phase of the first sound signal. By doing so, the synthesis sound pressure of the sound output from the first speaker 121 and the sound output from the second speaker 122 at the sound receiving point R can be restrained. Since M/N is the same as the volume velocity ratio between the two speakers, setting the amplitude of the third sound signal to be supplied to the second speaker 122 to the value M/N times as high as the amplitude of the first sound signal output from the sound signal generating unit 111 is equivalent to setting the amplitude ratio between the sound signals of the two speakers to the value equal to the volume velocity ratio between the two speakers.

Next, the delay time calculating operation to be performed by the delay time determining unit 1813 is described. Using the equation (21), the synthesis sound pressure at a given location L can be minimized through the control of the delay time.

First, variables a, b, c, and d are defined as shown in the equations (26), and the equation (21) can be modified to the following equation (27):

$$\begin{matrix}a = {\sum }_{j = 1}^{N} \frac{cos {kr}_{si}}{{r}_{si}} , \\ b = - {\sum }_{j = 1}^{N} \frac{sin {kr}_{si}}{{r}_{si}} , \\ c = {\sum }_{i = 1}^{M} \frac{cos {kr}_{pi}}{{r}_{pi}} , \\ d = - {\sum }_{i = 1}^{M} \frac{sin {kr}_{pi}}{{r}_{pi}} & ( 26 ) \\ η = 20 log \vert 1 + \frac{\vert {q}_{s} \vert {ⅇ}^{{jθ}_{s}}}{\vert {q}_{p} \vert {ⅇ}^{{jθ}_{p}}} \cdot \frac{a + jb}{c + jd} \vert & ( 27 )\end{matrix}$$

Further, with variables A and B expressed by the following equations (28), the equation (27) can be modified to the following equation (29):

$$\begin{matrix}A = \frac{a c + bd}{{c}^{2} + {d}^{2}} , B = \frac{bc - ad}{{c}^{2} + {d}^{2}} & ( 28 ) \\ η = 20 log \vert 1 + \frac{\vert {q}_{s} \vert \cdot {ⅇ}^{{jθ}_{s}}}{\vert {q}_{p} \vert \cdot {ⅇ}^{{jθ}_{p}}} \cdot ( A + jB ) \vert & ( 29 )\end{matrix}$$

As shown in the equation (29), the variable A is a real term, and the variable B is an imaginary term. When the equations (24) expressing the amplitude and the phase of the additional sound source calculated by the amplitude and phase adjusting unit 1812 are assigned to the equation (29), the following modified equation (30) can be obtained:

$$η = 20 log \vert 1 - \frac{M}{N} \cdot ( A + jB ) \vert \qquad ( 30 )$$

Here, a variable γ is defined as expressed by the following equation (31), which is then modified to the following equation (32):

$$\begin{matrix}γ = \vert 1 - \frac{M}{N} \cdot ( A + jB ) \vert & ( 31 ) \\ γ = \sqrt{{( 1 - \frac{M}{N} \cdot A )}^{2} + {( - \frac{M}{N} \cdot B )}^{2}} & ( 32 )\end{matrix}$$

In accordance with the equation (32), when the imaginary term B becomes zero, the variable γ becomes less than 1 as shown in the following equation (33). When the ream term A becomes zero, the variable γ becomes larger than 1 as shown in the following equation (34).

$$\begin{matrix}γ = ( 1 - \frac{M}{N} \cdot A ) < 1 & ( 33 ) \\ γ = \sqrt{1 + {( - \frac{M}{N} \cdot B )}^{2}} > 1 & ( 34 )\end{matrix}$$

Accordingly, so as to maximize the decrease in sound pressure level, or to approximate the variable γ that is the value in the absolute value brackets in the equation (30) expressing the decrease in sound pressure level to zero, the imaginary term B should be made zero. However, since the terms A and B are uniquely determined by the given location L, the term B cannot be adjusted to zero at the given location L.

Therefore, the phase of the sound signal to be supplied to the additional sound source is further varied by θ, so that the imaginary term B is assumed to be zero at the given location L. Varying the phase of a sound signal is equivalent to controlling the delay time between sound signals. If the imaginary term B can be made zero by varying the phase, the synthesis sound pressure at the given location L can be minimized by controlling the delay time.

In the following, the procedures for varying the phase to make the imaginary term B zero are described. First, θ is assigned to the phase in the complex amplitude obtained from the equation (25), and the following equation (35) can be obtained:

$${q}_{s} = \frac{N}{M} \vert {q}_{p} \vert \cdot {ⅇ}^{j ( {θ}_{p} + π )} \cdot {ⅇ}^{jθ} \qquad ( 35 )$$

When the equation (35) is substituted for the equation (29), the following equation (36) is obtained:

$$η = 20 log \vert 1 - \frac{M}{N} \cdot \{ ( A cos θ - B sin θ ) + j ( A sin θ + B cos θ ) \} \vert \qquad ( 36 )$$

Since the imaginary number part in the equation (36) is to be made zero, the following equation (37) is obtained:
A sin θ+B cos θ=0 (37)

The equation (37) can be modified to the following equation (38), and the phase θ can be expressed by the following equation (39):

$$\begin{matrix}\begin{matrix}\frac{sin θ}{cos θ} = tan θ \\ = - \frac{B}{A} \\ = - \frac{bc - ad}{ac + bd} \\ = - \frac{\begin{matrix}- {\sum }_{i = 1}^{N} \frac{sin {kr}_{Si} ( L )}{{r}_{Si} ( L )} \cdot {\sum }_{i = 1}^{M} \frac{cos {kr}_{Pi} ( L )}{{r}_{Pi} ( L )} + \\ {\sum }_{i = 1}^{N} \frac{cos {kr}_{Si} ( L )}{{r}_{Si} ( L )} \cdot {\sum }_{i = 1}^{M} \frac{sin {kr}_{Pi} ( L )}{{r}_{Pi} ( L )}\end{matrix}}{\begin{matrix}{\sum }_{i = 1}^{N} \frac{cos {kr}_{Si} ( L )}{{r}_{Si} ( L )} \cdot {\sum }_{i = 1}^{M} \frac{cos {kr}_{Pi} ( L )}{{r}_{Pi} ( L )} - \\ {\sum }_{i = 1}^{N} \frac{sin {kr}_{Si} ( L )}{{r}_{Si} ( L )} \cdot {\sum }_{i = 1}^{M} \frac{sin {kr}_{Pi} ( L )}{{r}_{Pi} ( L )}\end{matrix}}\end{matrix} & ( 38 ) \\ θ ( L , f ) = {tan}^{- 1} \{ - \frac{\begin{matrix}- {\sum }_{i = 1}^{N} \frac{sin {kr}_{Si} ( L )}{{r}_{Si} ( L )} \cdot {\sum }_{i = 1}^{M} \frac{cos {kr}_{Pi} ( L )}{{r}_{Pi} ( L )} + \\ {\sum }_{i = 1}^{N} \frac{cos {kr}_{Si} ( L )}{{r}_{Si} ( L )} \cdot {\sum }_{i = 1}^{M} \frac{sin {kr}_{Pi} ( L )}{{r}_{Pi} ( L )}\end{matrix}}{\begin{matrix}{\sum }_{i = 1}^{N} \frac{cos {kr}_{Si} ( L )}{{r}_{Si} ( L )} \cdot {\sum }_{i = 1}^{M} \frac{cos {kr}_{Pi} ( L )}{{r}_{Pi} ( L )} - \\ {\sum }_{i = 1}^{N} \frac{sin {kr}_{Si} ( L )}{{r}_{Si} ( L )} \cdot {\sum }_{i = 1}^{M} \frac{sin {kr}_{Pi} ( L )}{{r}_{Pi} ( L )}\end{matrix}} \} & ( 39 )\end{matrix}$$

Here, the wavenumber k can be expressed by k=2 πf/C, where f represents the frequency and C represents the sound velocity.

With the given location L being provided, the decrease in sound pressure level at the location L can be maximized by varying the phase of the sound signal by the phase θ calculated according to the equation (39). Further, using the angular frequency ω=2 πf, the relationship between the delay time T and the phase θ can be expressed by the following equation (40):

$$T = \frac{θ}{ϖ} [ sec ] \qquad ( 40 )$$

Accordingly, the delay time T can be calculated so as to maximize the decrease in sound pressure level at the location L.

The characteristics observed in the relationship between the frequency and the phase (the delay time) calculated in the above manner are now described. FIG. 19 shows the relationship between frequency and phase. In FIG. 19, the abscissa axis indicates the frequency f (Hz), and the ordinate axis indicates the phase θ (deg). The graph shows the relationship between the frequency and the phase calculated according to the equation (39) for cases where the location L (m) to maximize the decrease in sound pressure level is 1 m, 2 m, and 5 m. In the graph, straight lines 1901, 1902, and 1903 indicate the relationship between the frequency and the phase in the cases of L=1 m, 2 m, and 5 m, respectively.

As shown in the graph, since the relationship between the frequency f and the phase θ is indicated by a primary line shape, the delay time T obtained by dividing the phase θ by each frequency 2 πf does not exhibit frequency dependence. At any location L (m), the decrease in sound pressure level can be maximized with the same delay time T (sec) in all the frequency bands. Accordingly, there is no need to control the delay time according to the frequency.

Further, unlike the case of measuring mechanical noise where the characteristics and the complex amplitudes of sound sources such as point sound sources, linear sound sources, and plane sound sources are unknown or are difficult to measure, the third embodiment concerns sound signals with which the characteristics and the complex amplitudes of the sound sources are known. Accordingly, the complex amplitude of an additional sound source calculated on the desk in relation to the main sound source can be implemented as control filters.

Next, an exemplary structure of the matrix speaker employed in the sound reproducing apparatus 1800 in accordance with the third embodiment, and the results of the region dividing operation performed by the structure are described.

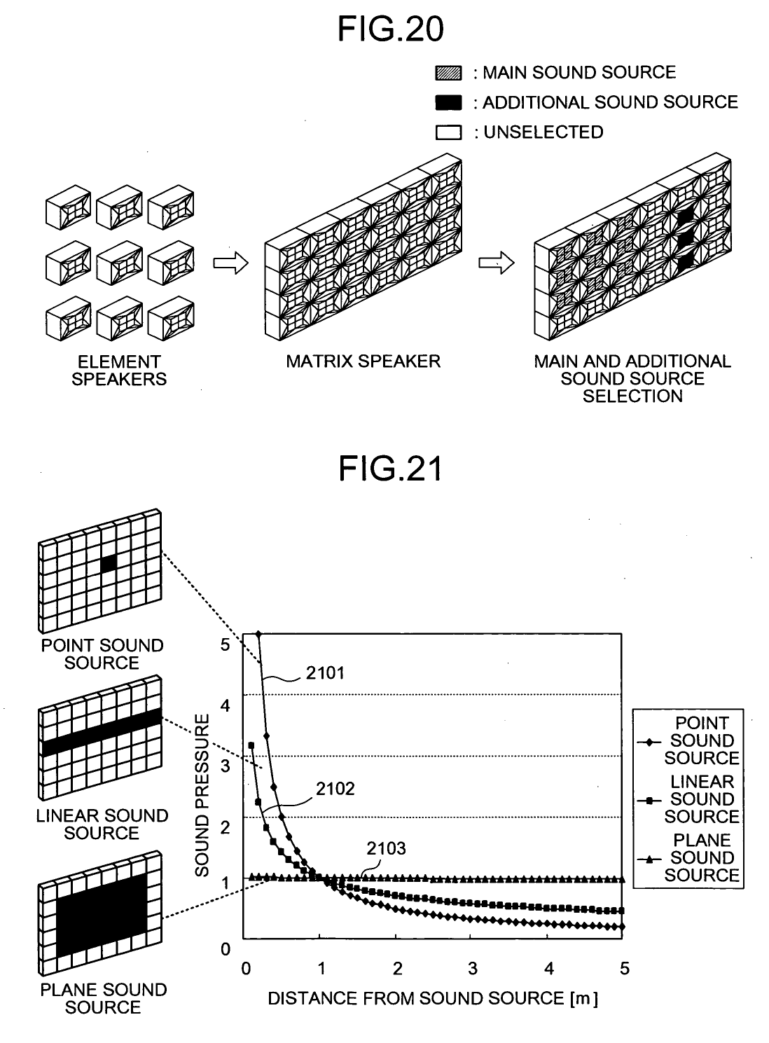

FIG. 20 shows the exemplary structure in which a main sound source and an additional sound source are selected from a matrix speaker formed with element speakers. As shown in the left-side part of FIG. 20, each element speaker is a rectangular parallelepiped. Thirty of such element speakers are arranged to form the matrix speaker shown in the middle part of FIG. 20. Further, as shown in the right-side part of FIG. 20, nine element speakers at the upper left part of the matrix speaker are selected as the main sound source, and three element speakers at the lower right part of the matrix speaker are selected as the additional sound source. The unselected element speakers are not to output sounds.

FIG. 21 shows the sound pressures of the sounds output from speakers selected from the matrix speaker so as to exhibit the characteristics of the point sound source, the linear sound source, and the plane sound source, in relation to the distance from each sound source.

As shown in FIG. 21, in a case where only one element speaker is selected, the sound source exhibits the characteristics of the point sound source, and has a distance decay rate of sound pressure as indicated by a curve 2101. When eight element speakers horizontally aligned in a row are selected, the sound source exhibits the characteristics of the linear sound source, and has a distance decay rate of sound pressure as indicated by a curve 2102. When 24 element speakers located in the center of the matrix speaker are selected, the sound source exhibits the characteristics of the plane sound source with sound pressure that does not decrease as indicated by a straight line 2103.

Accordingly, two speakers with different distance decay rates from each other can be formed by varying the number and the location of element speakers selected from the matrix speaker. Using such two speakers, region dividing can be performed in the above described manner.

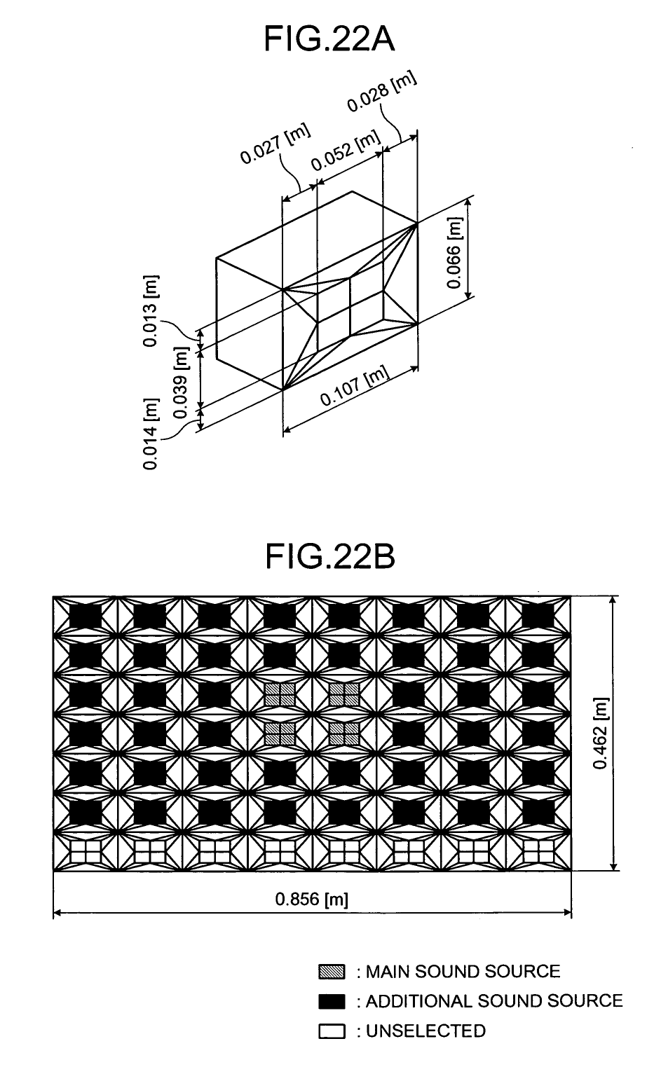

FIGS. 22 through 25 show a more specific exemplary structure of the matrix speaker as described above, and show the experiment results of region dividing performed with the exemplary structure.

FIGS. 22A and 22B show an exemplary structure in which a main sound source and an additional sound source are selected from a matrix speaker formed with element speakers. In the example shown in FIG. 22B, four middle element speakers are selected as the first speaker 121, and 44 element speakers are selected as the second speaker 122 from the matrix speaker that has 56 element speakers arranged in seven rows and eight columns. Each of the element speakers has the exterior size of 0.066 (m) in height and 0.107 (m) in width, and has the active area of 0.039 (m) in height and 0.052 (m) in width. The element speakers in the lowermost row are unselected.

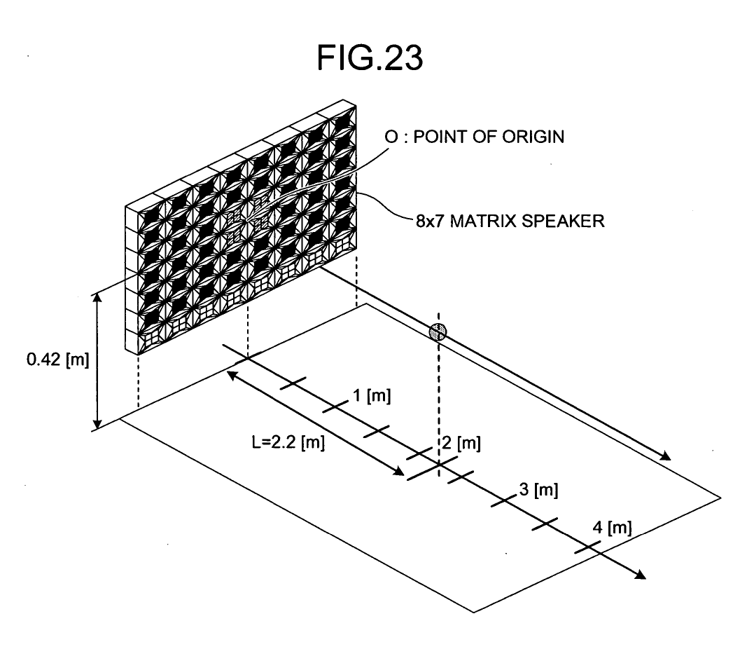

FIG. 23 shows conditions for placement of the matrix speaker shown in FIG. 22A. As shown in FIG. 23, the point of origin of three-dimensional space coordinates is set in the center of the first speaker 121, and the distance from the point of origin to the floor face is 0.42 (m). When the location to minimize the synthesis sound pressure is set at 2.2 (m) from the point of origin, the delay time T is 0.055 (msec) in accordance with the equation (40). The main sound source is delayed by the calculated delay time T with respect to the additional sound source. By doing so, the sound output from the main sound source can be prevented from reaching the synthesis sound pressure point earlier than the sound output from the additional sound source. Even if the sound is of a random type, the sound pressure can be interfered at the synthesis sound pressure point, and can be reduced accordingly.

When the subject apparatus is to reduce noise like an active noise reduction device, sound cannot be output from the additional sound source prior to generation of noise, and the output of the noise as the main sound source cannot be delayed. In the sound reproducing apparatus 1800, on the other hand, the sound signal to be output from the main sound source can be controlled. Instead of advancing the sound to be output from the additional sound source, the sound signal to be output from the main sound source can be delayed.

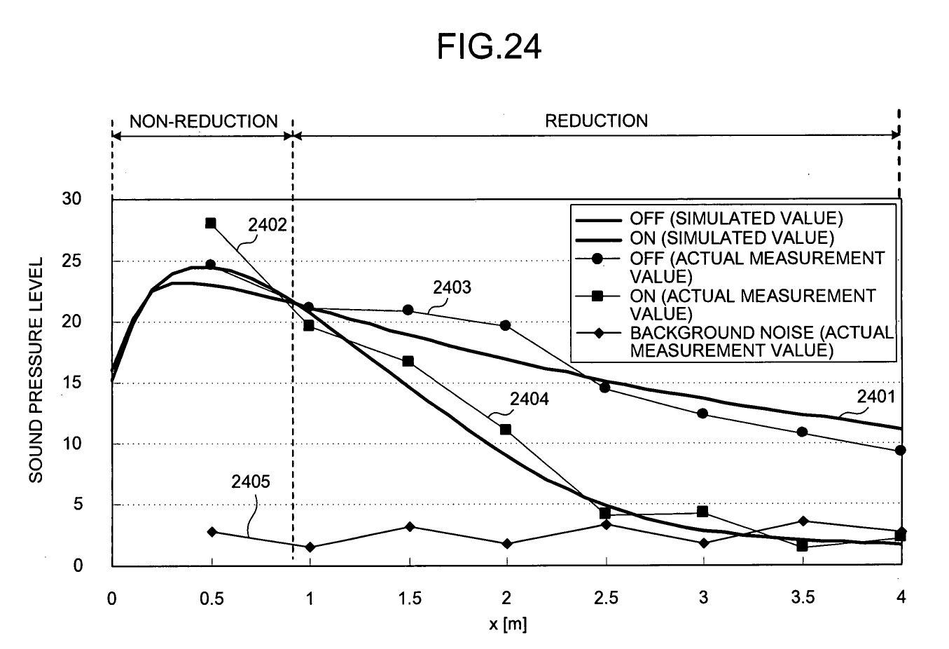

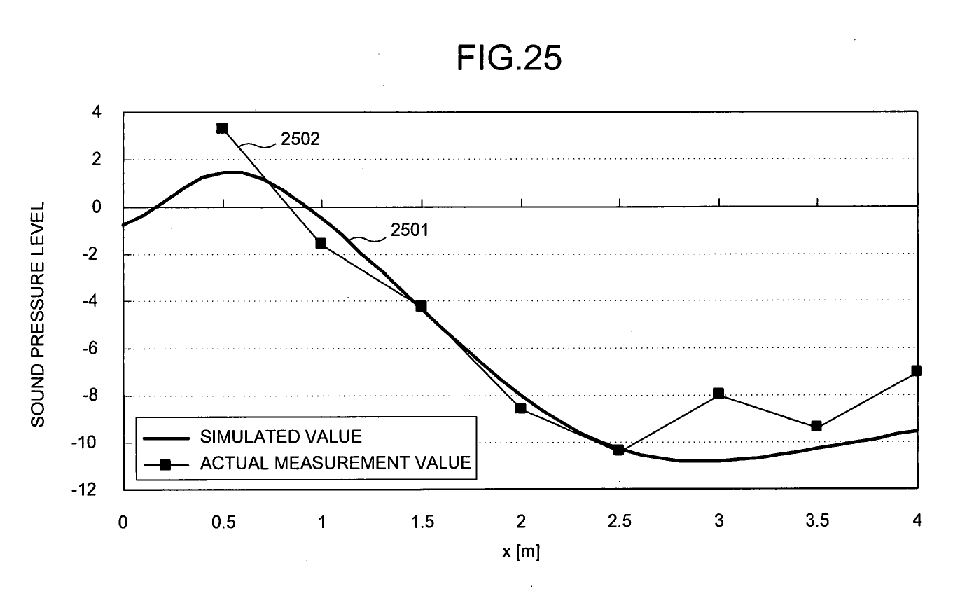

FIGS. 24 and 25 show the relationship between the sound pressure level (dB) and the distance (m) from the matrix speaker, and the relationship between the decrease in sound pressure level (dB) and the distance (m) from the matrix speaker, under the above described conditions. In FIG. 24, values calculated through simulations and actual measurement values by 0.5 (m) are shown with respect to the variation of the sound pressure level on the floor face at a distance of 4 (m) from the front face of the matrix speaker.

In FIG. 24, graphs 2401, 2402, 2403, 2404, and 2405 represent the calculated values prior to control, the calculated values after control, the actual measurement values prior to control, the actual measurement values after control, and the actual measurement values of background noise, respectively. Here, “prior to control” means the state in which sound is output only from the main sound source, and “after control” means the state in which region dividing is performed with the addition of the additional sound source.

In FIG. 25, values calculated through simulations and actual measurement values by 0.5 (m) are shown with respect to the variation of the decrease in sound pressure level on the floor face at a distance of 4 (m) from the front face of the matrix speaker. Here, the “decrease in sound pressure level” is the difference in sound pressure level between before and after “control”. In FIG. 25, graphs 2501 and 2502 represent the calculated values and the actual measurement values of the decreases in sound pressure level.

As shown in FIGS. 24 and 25, through the comparison between the calculated values and the actual measurement values, the variations are almost the same, and the generation of the expected two regions, i.e., a non-reduction region and a reduction region are observed. Further, as shown in FIG. 25, generation of such a point as to maximize the decrease in sound pressure level can be observed, though the point is slightly different from the preset point at such a distance of 2.2 (m) as to minimize the synthesis sound pressure.

As described so far, in the sound reproducing apparatus 1800 in accordance with the third embodiment, two speakers, that are selected from the speakers arranged in a matrix fashion and that have different distance decay rates from each other, output such sounds as to restrain the synthesis sound pressure of the sounds output from the speakers at a predetermined location. Accordingly, the sound field can be divided into a non-reduction region and a reduction region, with the predetermined location serving as the boundary. In this manner, region dividing can be performed even in such a speaker layout as an integrated type layout in which freedom is not allowed in the arrangement of the main sound source and the additional sound source.

A sound reproducing program to be executed in the sound reproducing apparatus of the first through third embodiments may be incorporated in a Read Only Memory (ROM) in advance.

Alternatively, the sound reproducing program to be executed in the sound reproducing apparatus of the first through third embodiments may be recorded beforehand on a computer-readable recording medium, such as a Compact Disk Read Only Memory (CD-ROM), a flexible disk (FD), a Compact Disk Recordable (CD-R), or a Digital Versatile Disk (DVD), in the form of an installable file or an executable file.

Further, the sound reproducing program to be executed in the sound reproducing apparatus of the first through third embodiments may be stored in a computer that is connected to a network such as the Internet. In this case, the sound reproducing program is downloaded via the network, prior to use. Further, the sound reproducing program to be executed in the sound reproducing apparatus of the first through third embodiments may be provided or distributed via a network such as the Internet.

The sound reproducing program to be executed in the sound reproducing apparatus of the first through third embodiments has a module structure that includes the above described units (the sound signal generating unit, the amplitude and phase adjusting unit, and the delay time determining unit). With actual hardware, the above described units are loaded into a main storage device by a Central Processing Unit (CPU) reading and executing the sound reproducing program from the ROM. Thus, the above functions are generated in the main storage device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A sound reproducing apparatus comprising:
an amplitude and phase adjusting unit that adjusts amplitude and phase of a sound signal which is supplied as an input, and outputs an adjusted sound signal;
a first sound source that outputs a first sound based on the sound signal; and
a second sound source that outputs a second sound based on the adjusted sound signal, and that has a different distance decay rate from the first sound source, the distance decay rate representing a ratio of attenuation of sound pressure of sound output from a sound source to a distance from the sound source;
wherein the amplitude and phase adjusting unit adjusts the amplitude and the phase of the sound signal, so as to restrain a synthesis sound pressure that is a combination of a sound pressure of the first sound which is calculated based on the distance decay rate of the first sound source, and a sound pressure of the second sound which is calculated based on the distance decay rate of the second sound source, at a predetermined distance from the first sound source.

2. The sound reproducing apparatus according to claim 1, further comprising
a sound pressure detecting unit that detects the synthesis sound pressure that is the combination of the sound pressure of the first sound and the sound pressure of the second sound at the predetermined distance from the first sound source,
wherein the amplitude and phase adjusting unit adjusts the amplitude and the phase of the sound signal based on the detected synthesis sound pressure.

3. The sound reproducing apparatus according to claim 1, wherein the first sound source and the second sound source exhibit characteristics of a point sound source and a linear sound source, respectively, with regards to the distance decay rates, or characteristics of a linear sound source and a point sound source, respectively.

4. The sound reproducing apparatus according to claim 1, wherein the first sound source and the second sound source exhibit characteristics of a linear sound source and a plane sound source, respectively, with regards to the distance decay rates, or characteristics of a plane sound source and a linear sound source, respectively.

5. The sound reproducing apparatus according to claim 1, wherein the first sound source and the second sound source exhibit characteristics of a point sound source and a plane sound source, respectively, with regards to the distance decay rates, or characteristics of a plane sound source and a point sound source, respectively.

6. The sound reproducing apparatus according to claim 1, wherein the first sound source and the second sound source exhibit characteristics of a linear sound source and a sound source having point sound sources disposed at both ends of a linear sound source, respectively, with regards to the distance decay rates, or characteristics of a sound source having point sound sources disposed at both ends of a linear sound source and a linear sound source, respectively.

7. A sound reproducing apparatus comprising:
a first sound source that has a length equal to or larger than a predetermined length in a predetermined direction, and outputs a first sound based on a first sound signal;
a second sound source that has a length equal to or smaller than the predetermined length in the predetermined direction, and outputs a second sound based on a second sound signal; and
an amplitude and phase adjusting unit that adjusts amplitude and phase of one of the first sound signal and the second sound signal to be input, so as to restrain a synthesis sound pressure which is a combination of a sound pressure of the first sound and a sound pressure of the second sound at a distance from one of the first sound source and the second sound source, the distance being longer than a distance represented by a value obtained by dividing the predetermined length by A, and that outputs the adjusted one of the first sound signal and the second sound signal as the other one of the first sound signal and the second sound signal.

8. A sound reproducing apparatus comprising:
an amplitude and phase adjusting unit that adjusts amplitude and phase of a sound signal which is supplied as an input, and outputs an adjusted sound signal;
a first sound source that is selected from a plurality of sound sources arranged in a matrix fashion;
a second sound source that is selected from the plurality of sound sources, and has a different distance decay rate from the first sound source, the distance decay rate representing a ratio of attenuation of sound pressure of sound output from a sound source to a distance from the sound source;
a delay time determining unit that determines a delay time for delaying the sound signal, so as to restrain a synthesis sound pressure which is a combination of a sound pressure of a sound output from the first sound source and a sound pressure of a sound output from the second sound source at a predetermined distance from the first sound source, and that outputs a delayed sound signal which is obtained by delaying the sound signal by the delay time to the first sound source;
wherein the amplitude and phase adjusting unit adjusts amplitude and phase of the sound signal, so as to restrain the synthesis sound pressure, and that outputs the adjusted sound signal to the second sound source.

9. The sound reproducing apparatus according to claim 8, wherein the amplitude and phase adjusting unit determines amplitude of the adjusted sound signal to be M/N times as high as the amplitude of the delayed sound signal (where M being a number of sound sources selected as the first sound source from the plurality of sound sources, and N being a number of sound sources selected as the second sound source from the plurality of sound sources), and determines the phase of the adjusted sound signal as the opposite of the phase of the delayed sound signal.

10. The sound reproducing apparatus according to claim 8, wherein the delay time determining unit calculates a delay time T for the delayed sound signal in accordance with an equation (1):
$$T = \frac{θ}{ϖ} [ sec ] \\ where \text{:} \\ θ ( L , f ) = {tan}^{- 1} \{ - \frac{\begin{matrix}- {\sum }_{i = 1}^{N} \frac{sin {kr}_{Si} ( L )}{{r}_{Si} ( L )} \cdot {\sum }_{i = 1}^{M} \frac{cos {kr}_{Pi} ( L )}{{r}_{Pi} ( L )} + \\ {\sum }_{i = 1}^{N} \frac{cos {kr}_{Si} ( L )}{{r}_{Si} ( L )} \cdot {\sum }_{i = 1}^{M} \frac{sin {kr}_{Pi} ( L )}{{r}_{Pi} ( L )}\end{matrix}}{\begin{matrix}{\sum }_{i = 1}^{N} \frac{cos {kr}_{Si} ( L )}{{r}_{Si} ( L )} \cdot {\sum }_{i = 1}^{M} \frac{cos {kr}_{Pi} ( L )}{{r}_{Pi} ( L )} - \\ {\sum }_{i = 1}^{N} \frac{sin {kr}_{Si} ( L )}{{r}_{Si} ( L )} \cdot {\sum }_{i = 1}^{M} \frac{sin {kr}_{Pi} ( L )}{{r}_{Pi} ( L )}\end{matrix}} \} \qquad ( 1 )$$
rₚᵢ(L) (1≦i≦M) represents a distance from each sound source forming the first sound source to a predetermined location L; and
rₛᵢ(L) (1≦i≦N) represents a distance from each sound source forming the second sound source to the predetermined location L;
K being 2 πf/C, where K represents wavenumber, f represents frequency, and C represents sound velocity, and
ω being 2 πf, where ω represents angular frequency.

11. A sound reproducing method comprising
adjusting amplitude and phase of a sound signal which is supplied as an input so as to restrain a synthesis sound pressure which is a combination of a sound pressure of a first sound output from a first sound source and a sound pressure of a second sound output from a second sound source at a predetermined distance from the first sound source, the first sound source outputting the first sound based on the sound signal, the second sound source outputting the second sound based on an adjusted sound signal and has a different distance decay rate from the first sound source, the distance decay rate representing a ratio of attenuation of sound pressure of sound output from a sound source to a distance from the sound source, and outputting the adjusted sound signal.

12. A sound reproducing method comprising
adjusting amplitude and phase of one of a first sound signal to be input to a first sound source and a second sound signal to be input to a second sound source, so as to restrain a synthesis sound pressure which is a combination of a sound pressure of a first sound and a sound pressure of a second sound at a distance from one of the first sound source and the second sound source, the distance being longer than a distance represented by a value obtained by dividing a predetermined length by π, the first sound source having a length equal to or larger than the predetermined length in a predetermined direction and outputting the first sound based on the first sound signal, the second sound source having a length equal to or smaller than the predetermined length in the predetermined direction and outputting the second sound based on the second sound signal, and outputting the adjusted one of the first sound signal and the second sound signal as the other one of the first sound signal and the second sound signal.

13. A sound reproducing method comprising:
determining a delay time for delaying a sound signal to be input to a first sound source selected from a plurality of sound sources arranged in a matrix fashion, so as to restrain a synthesis sound pressure which is a combination of a sound pressure of a sound output from the first sound source and a sound pressure of a sound output from a second sound source at a predetermined distance from the first sound source, the second sound source having a different distance decay rate from the first sound source and being selected from the plurality of sound sources, the distance decay rate representing a ratio of attenuation of sound pressure of sound output from a sound source to a distance from the sound source, and outputting a delayed sound signal which is obtained by delaying the sound signal by the delay time to the first sound source; and
adjusting amplitude and phase of the sound signal, so as to restrain the synthesis sound pressure, and outputting an adjusted sound signal to the second sound source.

14. A computer program product having a computer readable medium including programmed instructions for performing sound reproduction, wherein the instructions, when executed by a computer, cause the computer to perform:
adjusting amplitude and phase of a sound signal which is supplied as an input so as to restrain a synthesis sound pressure which is a combination of a sound pressure of a first sound output from a first sound source and a sound pressure of a second sound output from a second sound source at a predetermined distance from the first sound source, the first sound source outputting the first sound based on the sound signal, the second sound source outputting the second sound based on an adjusted sound signal and has a different distance decay rate from the first sound source, the distance decay rate representing a ratio of attenuation of sound pressure of sound output from a sound source to a distance from the sound source, and outputting the adjusted sound signal.

15. A computer program product having a computer readable medium including programmed instructions for performing sound reproduction, wherein the instructions, when executed by a computer, cause the computer to perform:
adjusting amplitude and phase of one of a first sound signal to be input to a first sound source and a second sound signal to be input to a second sound source, so as to restrain a synthesis sound pressure which is a combination of a sound pressure of a first sound and a sound pressure of a second sound at a distance from one of the first sound source and the second sound source, the distance being longer than a distance represented by a value obtained by dividing a predetermined length by π, the first sound source having a length equal to or larger than the predetermined length in a predetermined direction and outputting the first sound based on the first sound signal, the second sound source having a length equal to or smaller than the predetermined length in the predetermined direction and outputting the second sound based on the second sound signal, and outputting the adjusted one of the first sound signal and the second sound signal as the other one of the first sound signal,and the second sound signal.

16. A computer program product having a computer readable medium including programmed instructions for performing sound reproduction, wherein the instructions, when executed by a computer, cause the computer to perform:
determining a delay time for delaying a sound signal to be input to a first sound source selected from a plurality of sound sources arranged in a matrix fashion, so as to restrain a synthesis sound pressure which is a combination of a sound pressure of a sound output from the first sound source and a sound pressure of a sound output from a second sound source at a predetermined distance from the first sound source, the second sound source having a different distance decay rate from the first sound source and being selected from the plurality of sound sources, the distance decay rate representing a ratio of attenuation of sound pressure of sound output from a sound source to a distance from the sound source, and outputting a delayed sound signal which is obtained by delaying the sound signal by the delay time to the first sound source; and
adjusting amplitude and phase of the sound signal, so as to restrain the synthesis sound pressure, and outputting an adjusted sound signal to the second sound source.
